(19) United States
(12) Patent Application Publication
(10) Pub. No.: US 2022/0222588 A1
(43) Pub. Date: Jul. 14, 2022

(54) AN AUTONOMOUS, INTEGRATED COMPUTER-ENABLED METHOD, SYSTEM, AND COMPUTER PROGRAM UTILISING AN ARTIFICIAL INTELLIGENCE ENGINE FOR DYNAMIC ALLOCATION AND OPTIMISATION OF SPACE, FURNITURE, EQUIPMENT AND/OR SERVICES

(71) Applicant: GRAND PERFORMANCE ONLINE PTY LTD, Sydney, New South Wales (AU)

(72) Inventor: Peter PETROULAS, Sydney (AU)

(21) Appl. No.: 17/607,396

(22) PCT Filed: Apr. 28, 2020
(86) PCT No.: PCT/AU2020/050414

§ 371 Date: Oct. 29, 2021

(30) Foreign Application Priority Data
Apr. 29, 2019 (AU) 2019901434
Aug. 19, 2019 (AU) 2019903016

(51) Int. Cl. G06Q 10/02; G06F 30/27

(52) U.S. Cl. CPC G06Q 10/02; G06F 30/27

(57) ABSTRACT

In one aspect, there is provided a computer-enabled method for optimising and allocating bookings to one or more spaces, the method optimising bookings to increase the probability of achieving a selected outcome. In one embodiment, the invention is directed to an online restaurant booking system that utilises an artificial intelligence engine to optimise the use of space, time, and other operational considerations of a restaurant in order to optimise desired outcomes which may include optimising capacity, ambiance, preferred seating allocation, extended booking duration times, variable and dynamic pricing options, menu and course options and other quantitative and qualitative criteria.

### TECHNICAL FIELD

The present invention relates to a system, method and computer program utilising an artificial intelligence engine for the dynamic optimisation and allocation of resources for defined spaces and time periods.

In one embodiment, the invention is directed to an online restaurant booking system that utilises an artificial intelligence engine to optimise the use of space, time, and other operational considerations of a restaurant in order to optimise desired outcomes which may include optimising capacity, ambiance, preferred seating allocation, extended booking duration times, variable and dynamic pricing options, menu and course options and other quantitative and qualitative criteria.

### BACKGROUND

To better understand the inventive concepts and embodiments of the invention described herein, an abridged history and of the restaurant industry and known booking systems is may be found in an earlier filed PCT application PCT/AU2018/051168 (and co-pending PCT application PCT/AU2018/051169, PCT/AU2018/051170 and PCT/AU2018/051171), as well an in Australian provisional application AU2019/900128.

Artificial intelligence is a term that originated in the field of computer science but has a broad and contestable definition. For the avoidance of doubt, in the context of the present specification, the term “artificial intelligence” when used to describe the functionality of software and/or hardware, refers to three broad types of “intelligence”, namely analytical, human-inspired and humanised artificial intelligence.

In the context of the present specification, the type of artificial intelligence referred to is analytical artificial intelligence—namely, the ability of the software to perform tasks that require some form of “cognitive intelligence”, including the ability to generate a cognitive representation of a real-world situation, and utilising past learning to inform future decisions.

### SUMMARY

In one aspect, there is provided a computer-enabled method for optimising and allocating bookings to one or more spaces, the method optimising bookings to increase the probability of achieving a selected outcome, comprising the steps of, receiving, at a pre-allocation module in communication with a processor, a booking request from a remote user interface via a communications network, the booking request including initial booking request information including at least a date and a time of the booking and a number of diners and a booking identifier, the pre-allocation module utilising the initial booking request information to determine whether the initial booking request information satisfies a plurality of booking constraints, whereby, if the request information does not satisfy one or more of the plurality of booking constraints, the pre-allocation module invokes an artificial intelligence module arranged to receive the request information and review one or more of the plurality of constraints including forecasted bookings and already accepted bookings to determine whether variation of the one or more constraints to allow acceptance of the booking request result in a greater maximisation in the probability of achieving the selected outcome, whereby if variation of the one or more constraints to allow acceptance of the booking request results in an increase in the probability of achieving the selected outcome, the one of more of the plurality of constraints are varied, and the initial booking request information is passed to an allocation module arranged to accept the booking request and allocate the booking request together with all previously received requests to one or more spaces in the venue, whereby if all booking requests can be allocated the received booking request is accepted, whereby the booking information is utilised to produce an optimised allocation instruction set saved on a database which is utilisable by one or more users associated with the venue.

In one embodiment, the varied constraints are utilised for all subsequent booking requests for the service period.

The method may comprise the further step of receiving customer information identifying the customer, utilising the customer identification information to locate information in one or more databases of customer preference information, the preference information including at least one of a customer's purchase and behavioural history, analysis of the customer's purchase and behavioural history, and customer preference information, whereby the preference information is utilised as an input to the artificial intelligence module.

The method may comprise the further step of receiving space information identifying the one or more spaces, utilising the space identification information to locate information in one or more databases of space constraint information, the space constraint information including at least one of a customer's historical use of the space, analysis of the customer's historical use of the space, the use of the space by other customers and attribute information of the space, whereby the space information is utilised as an input to the artificial intelligence module.

The method may include the further step of locating operational information in one or more databases of operational information, the operational information including at least one of historical information regarding bottlenecks, benchmarks, problems, opportunities or other information relevant to the utilisation provision of the space, and analysis of the bottlenecks, problems, opportunities or other information relevant to the utilisation provision of the space, whereby the operational information is utilised as an input to the artificial intelligence module.

The method may include the further step of utilising an artificial intelligence module to select one of a plurality of allocation modules.

The method may include the further step of utilising an artificial intelligence module to alter the allocation module.

The method may include the further step of utilising a forecasting artificial intelligence module to provide information to the allocation module.

The method may include the further step of utilising a voice recognition artificial intelligence module to provide information to the allocation module.

The method may include the further step of utilising a robotic device artificial intelligence module to provide information to the allocation module or receive information from the allocation module and booking process to transmit instructions to a robotic device.

The method may include the further step of the artificial intelligence module, upon receiving initial booking information, utilising actual and forecasted booking profile information to determine whether the one or more of the plurality of constraints should be varied to ensure that the one or more plurality of constraints are met so as to permit the booking request to be passed onto the allocation module and for the allocation module to attempt allocation.

The booking profile may include a summary of information from one or more databases including historical booking and revenue information, forecast information, personal preference and activity information, historical booking pattern information, third-party industry information, and Internet-sourced information including social trends and event information.

The method may include the further step of the allocation module, upon receiving the booking request, determining whether the booking is allocable and if so, allocating the booking, and if not, one of placing the booking on a waitlist or offering the booking requestor one or more alternative potential bookings.

The method may include the further step of the allocation module communicating with a booking database to determine whether existing booking have been made for the service period, and if so, utilising the processor to retrieve information regarding the existing bookings, whereby the booking request and the bookings form a pool of requests, whereby the allocation module allocate the request and reallocates the existing bookings iteratively to generate a revised optimised allocation instruction set.

The received booking request may be allocated if all other bookings are capable of allocation.

The method may include the further step of the allocation module communicating with a waitlist database, to determine whether requests for one or more spaces are awaiting allocation, and if so, the processor retrieves information regarding the waitlist requests and combines the booking request with the existing bookings and one or more of the waitlist requests to form a pool of requests, whereby the allocation module allocates all requests from the pool of requests iteratively to generate a revised optimised allocation instruction set.

One or more of the waitlist requests may be allocated if the booking request and all other bookings are allocable.

In one embodiment, the pre-allocation module, upon receiving the initial booking request information, determines a further constraint that must be satisfied in order for the initial booking request to be satisfied, and provides information regarding the further constraint to the remote interface, whereby the interface is prompted to provide further input regarding the further constraint, whereby the information regarding the further constraint is provided to the pre-allocation module to determine whether the initial booking request information continues to satisfy the plurality of constraints, and if so, the booking request is passed to the allocation module, and if not, the booking request is passed to the artificial intelligence module.

In one embodiment, the pre-allocation module, in response to one or more further constraints, iteratively prompts the interface for information regarding further constraints until all constraints are satisfied and the booking request can be passed to the allocation module.

In one embodiment, the allocation module utilises the venue constraint information and requestor constraint information as inputs to a booking algorithm to allocate the booking request.

In a further aspect, the invention provides a computer-enabled method for optimising and allocating bookings to one or more spaces, the method optimising bookings to maximise the probability of achieving a selected outcome, comprising the steps of, receiving, at an allocation module in communication with a processor, a booking request from a remote user interface via a communications network, the booking request including initial booking request information including at least a date and a time of the booking and a number of people and a booking identifier, and accessing a database of previously accepted booking requests for the service period and combining the previously accepted booking requests with the booking request to form a pool of booking requests, whereby the booking allocation algorithm utilises the varied plurality of constraints including forecasted bookings and accepted bookings and venue constraint information regarding dimensions, shape, and attributes of the one or more spaces in the venue, dimensions and shape of one or more available furniture that may be allocated to the one or more spaces in the venue, to attempt to allocate the booking request, whereby, on attempting to allocate all bookings in the pool of booking requests and determining that all booking requests in the pool of booking requests cannot be allocated utilising the venue and requestor constraint information, invoking a booking artificial intelligence algorithm arranged to receive the pool of booking requests and venue and requestor constraint information, and review the venue and requestor constraint information and a plurality of booking rules and attempt to allocate all booking requests by varying one or more of the plurality of constraints and rules in a manner such that one or more optimisation conditions maximise the probability of achieving the selected outcome, whereby if one or more of the plurality of constraints and rules, upon review, would result in the allocation of all booking requests, the one of more of the plurality of constraints and rules are varied and all booking requests are allocated, whereby the booking information is utilised to produce an optimised allocation instruction set saved on a database which is utilisable by one or more users associated with the venue.

The allocation constraints as determined by an artificial intelligence module may include information to determine whether the received booking request is to be categorised into one or more categories of booking types.

The categories may include a class category and a Very Important Person (VIP) category.

In one embodiment, the categories include a ranking of a table associated with one of the one or more spaces and a location of the table within the one of the one or more spaces, whereby a hierarchy of tables within the class category is utilised in the allocation of the booking request.

The method may include the further step of the artificial intelligence module receiving booking requestor identity information received from one or more third-party databases of information, whereby the requestor identity information is utilised to rank one or more booking requestors and to vary the VIP status of the booking requestor.

The method may include the further step of an artificial intelligence menu module varying a menu and/or courses associated with the one or more spaces during the service period dependent on the constraint information provided by the booking requestor.

The constraint information may include the requested group size or other information determined and provided by an artificial intelligence module.

The method may include the further step of utilising the booking request information and an artificial intelligence module to determine the revenue potential for a particular combination of at least two of the menu, the group size and the service period of the booking request, whereby the options offered to the booking requestor are varied to optimise the revenue potential of the restaurant.

The method may include the further step of using an artificial intelligence module comprising the further step of utilising at least one of the historical menu variations and the revenue potential to forecast future demand for resources associated with the venue.

The method may include the further step of using an artificial intelligence module to varying a demand profile utilising at least one of date, service, time, occasion and group size to calculate dynamic pricing changes or changes to optimise use of the one or more spaces of the venue.

The allocation instruction set may be formatted for display of all boking information to the one or more users associated with the venue, via a space allocation graphical user interface.

The allocation instruction set may be displayed as a map including table location and seating details for all allocated bookings on a graphical representation of the one or more spaces variable by time.

The allocation instruction set may be associated with the booking are formatted to allow display of relevant allocation instructions to the booking requestor via a graphical user interface.

The relevant allocation instructions may be displayed as a table location and seating details on a graphical representation of the one or more spaces.

The method may further include the step of receiving feedback information from the at least one of the users associated with the venue, wherein the feedback information is utilised to vary one of the constraints and the conditions associated with a booking request.

In another aspect, the invention provides computer-enabled method for optimising and allocating bookings to one or more spaces in a manner that achieves a desired outcome, comprising the steps of, receiving, at a pre-allocation module in communication with a processor, a booking request from a remote user interface via a communications network, the booking request including initial booking request information including at least a date and a time of the booking and a number of people for the booking, the pre-allocation module utilising the initial booking request information to determine whether the initial booking request information satisfies a plurality of constraints, whereby, if the request information does not satisfy one or more of the plurality of constraints, the pre-allocation module invokes an artificial intelligence module arranged to receive the request information and review one or more of the plurality of constraints including forecasted bookings and already accepted bookings in a manner such that one or more optimisation conditions are more likely to result in the desired outcome, whereby if one or more of the plurality of constraints, upon review, would result in the booking request, if accepted, being more likely to result in the desired outcome, the one of more of the plurality of constraints are varied, and the initial booking request information is passed to an allocation module arranged to allocate the booking request to one or more spaces in the venue, whereby the allocation module utilises the varied plurality of constraints and venue constraint information regarding the venue including information regarding floor plans including tables and table combinations for each of the one or more spaces in the venue, to attempt to allocate the booking request, whereby the booking information is utilised to produce an optimised allocation instruction set saved on a database which is utilisable by one or more users associated with the venue.

The method may include the further step of receiving customer information identifying the customer, utilising the customer identification information to locate information in one or more databases of customer preference information, the preference information including at least one of a customer's purchase and behavioural history, analysis of the customer's purchase and behavioural history, and customer preference information, whereby the preference information is utilised as an input to the artificial intelligence module.

The method may include the further step of receiving space information identifying the one or more spaces, utilising the space identification information to locate information in one or more databases of space constraint information, the space constraint information including at least one of a customer's historical use of the space, analysis of the customer's historical use of the space, and attribute information of the space, whereby the space information is utilised as an input to the artificial intelligence module.

The method may include the further step of locating operational information in one or more databases of operational information, the operational information including at least one of historical information regarding bottlenecks, benchmarks, problems, opportunities or other information relevant to the utilisation of the space, and analysis of the bottlenecks, problems, opportunities or other information relevant to the utilisation of the space, whereby the operational information is utilised as an input to the artificial intelligence module.

The method may include the further step of utilising an artificial intelligence module to select one of a plurality of allocation modules.

The method may include the further step of utilising an artificial intelligence module to alter the allocation module.

The method may include the further step of utilising a forecasting artificial intelligence module to provide information to the allocation module.

The method may include the further step of utilising a voice recognition artificial intelligence module to provide information to the allocation module.

The method may include the further step of utilising a robotic device artificial intelligence module to provide information to the allocation module.

The method may include the further step of accessing a database of previously accepted booking requests for the service period and combining the previously accepted booking requests with the booking request to form a pool of booking requests, whereby the booking allocation algorithm, on attempting to allocate all bookings in the pool of booking requests, determining that all booking requests in the pool of booking requests cannot be allocated utilising the venue and requestor constraint information, invokes a booking artificial intelligence algorithm arranged to receive the pool of booking requests and venue and requestor constraint information, and review the venue and requestor constraint information including forecasted bookings and already accepted bookings and a plurality of booking rules and attempt to allocate all booking requests by varying one or more of the plurality of constraints and rules in a manner such that one or more optimisation conditions are more likely to result in the desired outcome, whereby if one or more of the plurality of constraints and rules, upon review, would result in the allocation of all booking requests, the one of more of the plurality of constraints and rules are varied and all booking requests are allocated.

In another aspect, the invention is directed to a computer-enabled method for optimising and allocating bookings to one or more tables and table combinations in a spaces, the method optimising bookings to maximise the probability of achieving a selected outcome, comprising the steps of, receiving, at a pre-allocation module in communication with a processor, a booking request from a remote user interface via a communications network, the booking request including initial booking request information including at least a date and a time of the booking and a number of diners and a booking identifier, the pre-allocation module utilising the initial booking request information to determine whether the initial booking request information satisfies a plurality of booking constraints, whereby, if the request information does not satisfy one or more of the plurality of booking constraints, the pre-allocation module invokes an artificial intelligence module arranged to receive the request information and review one or more of the plurality of constraints including forecasted bookings and already accepted bookings to determine whether variation of the one or more constraints to allow acceptance of the booking request result in a greater maximisation in the probability of achieving the selected outcome, whereby if variation of the one or more constraints to allow acceptance of the booking request results in a maximisation in the probability of achieving the selected outcome, the one of more of the plurality of constraints are varied and the varied constraints are may or may not be utilised for all subsequent booking requests for the service period, and the initial booking request information is passed to an allocation module arranged to accept the booking request and allocate the booking request together with all previously received requests to one or more tables and table combinations in a spaces in the venue, whereby if all booking requests can be allocated the received booking request is accepted, whereby the booking information is utilised to produce an optimised allocation instruction set saved on a database which is utilisable by one or more users associated with the venue.

The method may include the further step of receiving customer information identifying the customer, utilising the customer identification information to locate information in one or more databases of customer preference information, the preference information including at least one of a customers purchase and behavioural history, analysis of the customer's purchase and behavioural history, and customer preference information, whereby the preference information is utilised as an input to the artificial intelligence module.

The method may include the further step of receiving space information identifying the one or more spaces, utilising the space identification information to locate information in one or more databases of space constraint information, the space constraint information including the relationships and relativities or each of the tables and table combinations with each other and the space, at least one of a customer's historical use of the space, analysis of the customer's historical use of the space, the use of the space by other customers and attribute information of the space, whereby the space information is utilised as an input to the artificial intelligence module.

The method may include the further step of locating operational information in one or more databases of operational information, the operational information including at least one of historical information regarding bottlenecks, problems, opportunities or other information relevant to the utilisation of the tables and tables combinations utilisation of the space, and analysis of the bottlenecks, problems, opportunities or other information relevant to the utilisation of the space, whereby the operational information is utilised as an input to the artificial intelligence module.

The method may include the further step of utilising an artificial intelligence module to select one of a plurality of allocation modules.

The method may include the further step of utilising an artificial intelligence module to alter the allocation module.

The method may include the further step of utilising a forecasting artificial intelligence module to provide information to the allocation module.

The method may include the further step of utilising a voice recognition artificial intelligence module to provide information to the allocation module.

The method may include the further step of utilising a robotic device artificial intelligence module to provide information to the allocation module or receive information from the allocation module and booking process to transmit instructions to a robotic device.

In another aspect, the invention provides a computer-enabled method for optimising and allocating bookings to one or more spaces for a defined period of time, the method optimising bookings to maximise the probability of achieving a selected outcome, comprising the steps of, receiving, at a pre-allocation module in communication with a processor, a booking request from a remote user interface via a communications network, the booking request including initial booking request information including at least a date and a time of the booking and a number of diners and a booking identifier, the pre-allocation module utilising the initial booking request information to determine whether the initial booking request information satisfies a plurality of booking constraints, whereby, if the request information does not satisfy one or more of the plurality of booking constraints, the pre-allocation module invokes an artificial intelligence module arranged to receive the request information and review one or more of the plurality of constraints including forecasted bookings and already accepted bookings to determine whether variation of the one or more constraints to allow acceptance of the booking request result in a greater maximisation in the probability of achieving the selected outcome, whereby if variation of the one or more constraints to allow acceptance of the booking request results in a maximisation in the probability of achieving the selected outcome, the one of more of the plurality of constraints are varied and the varied constraints are may or may not be utilised for all subsequent booking requests for the service period, and the initial booking request information is passed to an allocation module arranged to accept the booking request and allocate the booking request together with all previously received requests for a defined period of time in a space in the venue, whereby if all booking requests can be allocated the received booking request is accepted, whereby the booking information is utilised to produce an optimised allocation instruction set saved on a database which is utilisable by one or more users associated with the venue.

The method may include the further step of receiving customer information identifying the customer, utilising the customer identification information to locate information in one or more databases of customer preference information, the preference information including at least one of a customers purchase and behavioural history, analysis of the customer's purchase and behavioural history, and customer preference information, whereby the preference information is utilised as an input to the artificial intelligence module.

The method may include the further step of receiving space information identifying the one or more spaces, utilising the space identification information to locate information in one or more databases of space constraint information, the space constraint information including at least one of a customer's historical use of the space, analysis of the customer's historical use of the space, and attribute information of the space, whereby the space information is utilised as an input to the artificial intelligence module.

The method may include the further step of locating operational information in one or more databases of operational information, the operational information including at least one of historical information regarding bottlenecks, problems, opportunities or other information relevant to the provision of the space, and analysis of the bottlenecks, problems, opportunities or other information relevant to the provision of the space, whereby the operational information is utilised as an input to the artificial intelligence module.

The method may include the further step of utilising an artificial intelligence module to select one of a plurality of allocation modules.

The method may include the further step of utilising an artificial intelligence module to alter the allocation module.

The method may comprise the further step of utilising a forecasting artificial intelligence module to provide information to the allocation module.

The method may comprise the further step of utilising a voice recognition artificial intelligence module to provide information to the allocation module.

The method may comprise the further step of utilising a robotic device artificial intelligence module to provide information to the allocation module or receive information from the allocation module and booking process to transmit instructions to a robotic device.

In another aspect, the invention provides a computer-enabled method for optimising and allocating bookings within a volumetric space/time framework to one or more spaces in a restaurant, the method optimising bookings to increase the probability of achieving a selected outcome, comprising the steps of, receiving, at a pre-allocation module in communication with a processor, a booking request from a remote user interface via a communications network, the booking request including initial booking request information including at least a date and a time of the booking and a number of attendees and a booking request identifier, the pre-allocation module utilising the initial booking request information to determine whether the initial booking request information satisfies a plurality of booking constraints, whereby, if the request information does not satisfy one or more of the plurality of booking constraints, the pre-allocation module invokes an artificial intelligence module arranged to receive the request information and review one or more of a plurality of spatial, product and service attributes to determine whether variation of the one or more constraints to allow acceptance of the booking request result in an increase in the probability of achieving the selected outcome, whereby if variation of the one or more attributes to allow acceptance of the booking request results in an increase in the probability of achieving the selected outcome, the one of more of the plurality of attributes are varied, and the varied attributes are utilised for all subsequent booking requests for the service period, and the initial booking request information is passed to an allocation module arranged to accept the booking request and allocate the booking request together with all previously received requests to one or more spaces in the venue.

In one embodiment, the method includes the further step of the artificial intelligence module, upon receiving initial booking information, utilising actual and forecasted booking profile information to determine whether the one or more of the plurality of constraints should be varied to ensure that the one or more plurality of constraints are met so as to permit the booking request to be passed onto the allocation module and for the allocation module to attempt allocation.

In one embodiment, the booking profile includes a summary of information from one or more databases including historical booking and revenue information, forecast information, personal preference and activity information, historical booking pattern information, third-party industry information, and Internet-sourced information including social trends and event information.

In one embodiment, the method includes the further step of the allocation module, upon receiving the booking request, determining whether the booking is allocable and if so, allocating the booking, and if not, one of placing the booking on a waitlist or offering the booking requestor one or more alternative potential bookings.

In one embodiment, the method includes the further step of the allocation module communicating with a booking database to determine whether existing booking have been made for the service period, and if so, utilising the processor to retrieve information regarding the existing bookings, whereby the booking request and the bookings form a pool of requests, whereby the allocation module allocate the request and reallocates the existing bookings iteratively to generate a revised optimised allocation instruction set.

In one embodiment, the received booking request is only allocated if all other bookings are capable of allocation.

In one embodiment, the method includes the further step of the allocation module communicating with a waitlist database, to determine whether requests for one or more spaces are awaiting allocation, and if so, the processor retrieves information regarding the waitlist requests and combines the booking request with the existing bookings and one or more of the waitlist requests to form a pool of requests, whereby the allocation module allocates all requests from the pool of requests iteratively to generate a revised optimised allocation instruction set.

In one embodiment, one or more of the waitlist requests are only allocated if the booking request and all other bookings are allocable.

In one embodiment, the instruction set is saved in an allocation database.

In one embodiment, the pre-allocation module, upon receiving the initial booking request information, determines a further constraint that must be satisfied in order for the initial booking request to be satisfied, and provides information regarding the further constraint to the remote interface, whereby the interface is prompted to provide further input regarding the further constraint, whereby the information regarding the further constraint is provided to the pre-allocation module to determine whether the initial booking request information continues to satisfy the plurality of constraints, and if so, the booking request is passed to the allocation module, and if not, the booking request is passed to the artificial intelligence module.

In one embodiment, the pre-allocation module, in response to one or more further constraints, iteratively prompts the interface for information regarding further constraints until all constraints are satisfied and the booking request can be passed to the allocation module.

In one embodiment, the allocation module utilises the venue constraint information and requestor constraint information as inputs to a booking algorithm to allocate the booking request.

In another aspect, the invention provides a computer-enabled method for optimising and allocating bookings to one or more spaces in a restaurant, the method optimising bookings to maximise the probability of achieving a selected outcome, comprising the steps of, receiving, at an allocation module in communication with a processor, a booking request from a remote user interface via a communications network, the booking request including initial booking request information including at least a date and a time of the booking and a number of people and a booking identifier, and accessing a database of previously accepted booking requests for the service period and combining the previously accepted booking requests with the booking request to form a pool of booking requests, whereby the booking allocation algorithm utilises the varied plurality of constraints and venue constraint information regarding dimensions, shape, and attributes of the one or more spaces in the venue, dimensions and shape of one or more available furniture that may be allocated to the one or more spaces in the venue, to attempt to allocate the booking request, whereby, on attempting to allocate all bookings in the pool of booking requests and determining that all booking requests in the pool of booking requests cannot be allocated utilising the venue and requestor constraint information, invoking a booking artificial intelligence algorithm arranged to receive the pool of booking requests and venue and requestor constraint information, and review the venue and requestor constraint information and a plurality of booking rules and attempt to allocate all booking requests by varying one or more of the plurality of constraints and rules in a manner such that one or more optimisation conditions maximise the probability of achieving the selected outcome, whereby if one or more of the plurality of constraints and rules, upon review, would result in the allocation of all booking requests, the one of more of the plurality of constraints and rules are varied and all booking requests are allocated.

In one embodiment, the allocation constraints include information to determine whether the received booking request is to be categorised into one or more categories of booking types.

In one embodiment, the categories include a class category and a Very Important Person (VIP) category.

In one embodiment, the categories include a ranking of a table associated with one of the one or more spaces and a location of the table within the one of the one or more spaces, whereby a hierarchy of tables within the class category is utilised in the allocation of the booking request.

In one embodiment, the method includes the further step of the artificial intelligence module receiving booking requestor identity information received from one or more third-party databases of information, whereby the requestor identity information is utilised to rank one or more booking requestors and to vary the VIP status of the booking requestor.

In one embodiment, the method includes the further step of a menu module varying a menu and/or courses associated with the one or more spaces during the service period dependent on the constraint information provided by the booking requestor.

In one embodiment, the constraint information includes the requested group size.

In one embodiment, the method includes the further step of utilising the booking request information to determine the revenue potential for a particular combination of at least two of the menu, the group size and the service period of the booking request, whereby the options offered to the booking requestor are varied to optimise the revenue potential of the restaurant.

In one embodiment, the method includes the further step of utilising at least one of the historical menu variations and the revenue potential to forecast future demand for resources associated with the venue.

In one embodiment, the method includes the further step of varying a demand profile utilising at least one of date, service, time, occasion and group size to calculate dynamic pricing changes or changes to optimise use of the one or more spaces of the venue.

In one embodiment, the allocation instruction set is formatted for display of all boking information to the one or more users associated with the venue, via a space allocation graphical user interface.

In one embodiment, the allocation instruction set is displayed as map including table location and seating details for all allocated bookings on a graphical representation of the one or more spaces.

In one embodiment, the allocation instruction set associated with the booking are formatted to allow display of relevant allocation instructions to the booking requestor via a graphical user interface.

In one embodiment, the relevant allocation instructions are displayed as a table location and seating details on a graphical representation of the one or more spaces.

In one embodiment, the method includes the step of receiving feedback information from the at least one of the users associated with the venue, wherein the feedback information is utilised to vary one of the constraints and the conditions associated with a booking request.

In another aspect, the invention provides a computer-enabled method for optimising and allocating bookings to one or more spaces in a restaurant in a manner that achieves a desired outcome, comprising the steps of, receiving, at a pre-allocation module in communication with a processor, a booking request from a remote user interface via a communications network, the booking request including initial booking request information including at least a date and a time of the booking and a number of people for the booking, the pre-allocation module utilising the initial booking request information to determine whether the initial booking request information satisfies a plurality of constraints, whereby, if the request information does not satisfy one or more of the plurality of constraints, the pre-allocation module invokes an artificial intelligence module arranged to receive the request information and review one or more of the plurality of constraints in a manner such that one or more optimisation conditions are more likely to result in the desired outcome, whereby if one or more of the plurality of constraints, upon review, would result in the booking request, if accepted, being more likely to result in the desired outcome, the one of more of the plurality of constraints are varied, and the initial booking request information is passed to an allocation module arranged to allocate the booking request to one or more spaces in the venue, whereby the allocation module utilises the varied plurality of constraints and venue constraint information regarding the venue including information regarding floor plans including tables and table combinations for each of the one or more spaces in the venue, to attempt to allocate the booking request.

In one embodiment, the method includes the further step of accessing a database of previously accepted booking requests for the service period and combining the previously accepted booking requests with the booking request to form a pool of booking requests, whereby the booking allocation algorithm, on attempting to allocate all bookings in the pool of booking requests, determining that all booking requests in the pool of booking requests cannot be allocated utilising the venue and requestor constraint information, invokes a booking artificial intelligence algorithm arranged to receive the pool of booking requests and venue and requestor constraint information, and review the venue and requestor constraint information and a plurality of booking rules and attempt to allocate all booking requests by varying one or more of the plurality of constraints and rules in a manner such that one or more optimisation conditions are more likely to result in the desired outcome, whereby if one or more of the plurality of constraints and rules, upon review, would result in the allocation of all booking requests, the one of more of the plurality of constraints and rules are varied and all booking requests are allocated.

In an aspect, the invention provides a computer-enabled method for optimising and allocating bookings to one or more spaces in a restaurant, the method optimising bookings to maximise the probability of achieving a selected outcome, comprising the steps of, receiving, at a pre-allocation module in communication with a processor, a booking request from a remote user interface via a communications network, the booking request including initial booking request information including at least a date and a time of the booking and a number of diners and a booking identifier, the pre-allocation module utilising the initial booking request information to determine whether the initial booking request information satisfies a plurality of booking constraints, whereby, if the request information does not satisfy one or more of the plurality of booking constraints, the pre-allocation module invokes an artificial intelligence module arranged to receive the request information and review one or more of the plurality of constraints to determine whether variation of the one or more constraints to allow acceptance of the booking request result in a greater maximisation in the probability of achieving the selected outcome, whereby if variation of the one or more constraints to allow acceptance of the booking request results in a maximisation in the probability of achieving the selected outcome, the one of more of the plurality of constraints are varied and the varied constraints are utilised for all subsequent booking requests for the service period, and the initial booking request information is passed to an allocation module arranged to accept the booking request and allocate the booking request together with all previously received requests to one or more spaces in the venue, whereby if all booking requests can be allocated the received booking request is accepted, whereby the booking information is utilised to produce an optimised allocation instruction set which is utilisable by one or more users associated with the venue.

In one embodiment, the method includes the further step of the artificial intelligence module, upon receiving initial booking information, utilising actual and forecasted booking profile information to determine whether the one or more of the plurality of constraints should be varied to ensure that the one or more plurality of constraints are met so as to permit the booking request to be passed onto the allocation module and for the allocation module to attempt allocation.

In one embodiment, the booking profile includes a summary of information from one or more databases including historical booking and revenue information, forecast information, personal preference and activity information, historical booking pattern information, third-party industry information, and Internet-sourced information including social trends and event information.

In one embodiment, the method includes the further step of the allocation module, upon receiving the booking request, determining whether the booking is allocable and if so, allocating the booking, and if not, one of placing the booking on a waitlist or offering the booking requestor one or more alternative potential bookings.

In one embodiment, the method includes the further step of the allocation module communicating with a booking database to determine whether existing booking have been made for the service period, and if so, utilising the processor to retrieve information regarding the existing bookings, whereby the booking request and the bookings form a pool of requests, whereby the allocation module allocate the request and reallocates the existing bookings iteratively to generate a revised optimised allocation instruction set.

In one embodiment, the received booking request is only allocated if all other bookings are capable of allocation.

In one embodiment, the method includes the further step of the allocation module communicating with a waitlist database, to determine whether requests for one or more spaces are awaiting allocation, and if so, the processor retrieves information regarding the waitlist requests and combines the booking request with the existing bookings and one or more of the waitlist requests to form a pool of requests, whereby the allocation module allocates all requests from the pool of requests iteratively to generate a revised optimised allocation instruction set.

In one embodiment, one or more of the waitlist requests are only allocated if the booking request and all other bookings are allocable.

In one embodiment, the instruction set is saved in an allocation database.

In one embodiment, the pre-allocation module, upon receiving the initial booking request information, determines a further constraint that must be satisfied in order for the initial booking request to be satisfied, and provides information regarding the further constraint to the remote interface, whereby the interface is prompted to provide further input regarding the further constraint, whereby the information regarding the further constraint is provided to the pre-allocation module to determine whether the initial booking request information continues to satisfy the plurality of constraints, and if so, the booking request is passed to the allocation module, and if not, the booking request is passed to the artificial intelligence module.

In one embodiment, the pre-allocation module, in response to one or more further constraints, iteratively prompts the interface for information regarding further constraints until all constraints are satisfied and the booking request can be passed to the allocation module.

In one embodiment, the allocation module utilises the venue constraint information and requestor constraint information as inputs to a booking algorithm to allocate the booking request.

In an aspect, there is provided a computer-enabled method for optimising and allocating bookings to one or more spaces in a restaurant, the method optimising bookings to maximise the probability of achieving a selected outcome, comprising the steps of,

receiving, at an allocation module in communication with a processor, a booking request from a remote user interface via a communications network, the booking request including initial booking request information including at least a date and a time of the booking and a number of people and a booking identifier, and accessing a database of previously accepted booking requests for the service period and combining the previously accepted booking requests with the booking request to form a pool of booking requests, whereby the booking allocation algorithm utilises the varied plurality of constraints and venue constraint information regarding dimensions, shape, and attributes of the one or more spaces in the venue, dimensions and shape of one or more available furniture that may be allocated to the one or more spaces in the venue, to attempt to allocate the booking request,

whereby, on attempting to allocate all bookings in the pool of booking requests and determining that all booking requests in the pool of booking requests cannot be allocated utilising the venue and requestor constraint information, invoking a booking artificial intelligence algorithm arranged to receive the pool of booking requests and venue and requestor constraint information, and review the venue and requestor constraint information and a plurality of booking rules and attempt to allocate all booking requests by varying one or more of the plurality of constraints and rules in a manner such that one or more optimisation conditions maximise the probability of achieving the selected outcome, whereby if one or more of the plurality of constraints and rules, upon review, would result in the allocation of all booking requests, the one of more of the plurality of constraints and rules are varied and all booking requests are allocated.

In one embodiment, the allocation constraints include information to determine whether the received booking request is to be categorised into one or more categories of booking types.

In one embodiment, the categories include a class category and a Very Important Person (VIP) category.

In one embodiment, the categories include a ranking of a table associated with one of the one or more spaces and a location of the table within the one of the one or more spaces, whereby a hierarchy of tables within the class category is utilised in the allocation of the booking request.

In one embodiment, the method includes the further step of the artificial intelligence module receiving booking requestor identity information received from one or more third-party databases of information, whereby the requestor identity information is utilised to rank one or more booking requestors and to vary the VIP status of the booking requestor.

In one embodiment, the method includes the further step of a menu module varying a menu and/or courses associated with the one or more spaces during the service period dependent on the constraint information provided by the booking requestor.

In one embodiment, the constraint information includes the requested group size.

In one embodiment, the method further includes the further step of utilising the booking request information to determine the revenue potential for a particular combination of at least two of the menu, the group size and the service period of the booking request, whereby the options offered to the booking requestor are varied to optimise the revenue potential of the restaurant.

In one embodiment, the method includes the further step of utilising at least one of the historical menu variations and the revenue potential to forecast future demand for resources associated with the venue.

In one embodiment, the method includes the further step of varying a demand profile utilising at least one of date, service, time, and occasion and group size to calculate dynamic pricing changes or changes to optimise use of the one or more spaces of the venue.

In one embodiment, the allocation instruction set is formatted for display of all boking information to the one or more users associated with the venue, via a space allocation graphical user interface.

In one embodiment, the allocation instruction set is displayed as map including table location and seating details for all allocated bookings on a graphical representation of the one or more spaces.

In one embodiment, the allocation instruction set associated with the booking are formatted to allow display of relevant allocation instructions to the booking requestor via a graphical user interface.

In one embodiment, the relevant allocation instructions are displayed as a table location and seating details on a graphical representation of the one or more spaces.

In one embodiment, the method further includes the step of receiving feedback information from the at least one of the users associated with the venue, wherein the feedback information is utilised to vary one of the constraints and the conditions associated with a booking request.

In an aspect, there is provided a computer-enabled method for optimising and allocating bookings to one or more spaces in a restaurant in a manner that achieves a desired outcome, comprising the steps of, receiving, at a pre-allocation module in communication with a processor, a booking request from a remote user interface via a communications network, the booking request including initial booking request information including at least a date and a time of the booking and a number of people for the booking, the pre-allocation module utilising the initial booking request information to determine whether the initial booking request information satisfies a plurality of constraints, whereby, if the request information does not satisfy one or more of the plurality of constraints, the pre-allocation module invokes an artificial intelligence module arranged to receive the request information and review one or more of the plurality of constraints in a manner such that one or more optimisation conditions are more likely to result in the desired outcome, whereby if one or more of the plurality of constraints, upon review, would result in the booking request, if accepted, being more likely to result in the desired outcome, the one of more of the plurality of constraints are varied, and the initial booking request information is passed to an allocation module arranged to allocate the booking request to one or more spaces in the venue, whereby the allocation module utilises the varied plurality of constraints and venue constraint information regarding the venue including information regarding floor plans including tables and table combinations for each of the one or more spaces in the venue, to attempt to allocate the booking request.

In one embodiment, the method comprises the further step of accessing a database of previously accepted booking requests for the service period and combining the previously accepted booking requests with the booking request to form a pool of booking requests, whereby the booking allocation algorithm, on attempting to allocate all bookings in the pool of booking requests, determining that all booking requests in the pool of booking requests cannot be allocated utilising the venue and requestor constraint information, invokes a booking artificial intelligence algorithm arranged to receive the pool of booking requests and venue and requestor constraint information, and review the venue and requestor constraint information and a plurality of booking rules and attempt to allocate all booking requests by varying one or more of the plurality of constraints and rules in a manner such that one or more optimisation conditions are more likely to result in the desired outcome, whereby if one or more of the plurality of constraints and rules, upon review, would result in the allocation of all booking requests, the one of more of the plurality of constraints and rules are varied and all booking requests are allocated.

In an aspect, the invention provides a computing system for optimising and allocating bookings within a space for a defined period of time in a venue, comprising an optimisation and allocation module in communication with a processor and arranged to receive the at least one request and communicate with a database to determine whether other requests for spaces have been made by other users, and if so, utilise the processor to retrieve information regarding the other requests for spaces and combine the at least one request with other requests to form a pool of requests, retrieve constraint information regarding the venue including information regarding the size of the venue and the size and quantity of available furniture that may be allocated to the space in the venue, and use an artificial intelligence engine to iteratively allocate all requests from the pool of requests utilising the restraint information to produce an optimised and/or prioritised allocation instruction set, wherein the optimised and/or prioritised allocation instruction set saved in the database and provided by a space allocation user interface to one or more users associated with the venue.

Firstly, with regards to tables the claimed invention uses spatial knowledge of the restaurant premises to create tables as required by the bookings received. As such, the artificial intelligence engine can add or remove tables from a restaurant's standard floor plan. From that perspective our first dimension can be said to be the restaurant floor plan (length and width) properly dimensioned and to scale with all objects in correct relativity. Then secondly, time is used as the other dimension to turn our two-dimensional floor plan from a single flat plane to a volumetric cube by introducing time as the other axis.

The artificial intelligence engine utilises a decision tree logic structure which seeks to find a “pathway” to a solution that it creates that not only optimises the allocation of bookings to tables, but also seeks to optimise the placement of tables. In effect, the engine optimises the number and placement of tables for the number of bookings, rather than simply trying to allocate bookings to a predetermined fixed number of tables and table combinations which have no spatial relationship to each other.

In addition, the decision tree which is encoded as part of the artificial intelligence engine is dynamic, in that the decision tree does not merely provide a series of “yes/no” gates, but rather, if as a consequence of the constraint information, a sub-optimal solution is provided, the claimed invention is able to iterate with varied conditions, in an attempt to create an optimised solution for the restaurant and the client.

As a corollary, the artificial intelligence engine does not require the input of tables and table combinations, as the starting premise for the claimed invention is not a predetermined number and/or layout of tables and table combinations. Rather, the claimed invention, upon receiving relevant constraint information, is tasked with not only allocating a booking to a table, but also allocating a table to an appropriate location in the space to achieve both qualitative and quantitative outcomes:

1. The claimed invention provides dynamic allocation of bookings, which may be optimised for a mixture of both quantitative and qualitative outcomes. This is achieved by the use of “spatial awareness” algorithms. Examples of the quantitative and qualitative outcomes include:
i. Quantitative Outcomes include:
a) Optimising one restaurant space before another restaurant space;
b) Optimising the whole restaurant and different spaces at the same time; and
c) Allocation of a booking to a specific table.
ii. Qualitative Outcomes include:
a) Allocating bookings to the “best” tables;
b) Leaving an empty table between bookings when the restaurant is not full to give bookings greater privacy; and
c) The allocation of a SVIP to their preferred table.
2. Moreover, as the algorithm has knowledge of the space and the furniture within the space, bookings can be allocated in a completely autonomous manner. In the description, it is clearly shown the underlying feature of “spatial awareness” allows completely autonomous restaurant management system from the time of the online restaurant booking request until the time a person leaves the restaurant other than the physical aspects of cooking the food, delivering the food and beverages to the table and cleaning and resetting a table.
3. The restaurant may also selectively choose the level of automation they wish to use within their restaurant. Hence the claimed invention can cater for anything from a casual café to a three Michelin star restaurant so no limitations or barriers exist in its industry applicability.
4. As the claimed invention has knowledge of the space, the invention can be utilised to optimise for almost any relevant desired outcome, whether it be revenue optimisation, cost minimisation or maximisation of the customer experience.

In one embodiment, the optimisation and/or prioritisation module iteratively allocates bookings to a table or a group of tables utilising constraint information arranged to create a particular ambiance within the space. The ambiance constraints in one embodiment include an algorithm that utilises artificial intelligence to review a series of inputs and allocate based on one or more of the following parameters:

1. The allocation of bookings to the best available tables when the restaurant or a space, sub-space, section or class is not forecasted or predicted to be required or full, taking into account potential late bookings and walk-in customers;
2. The upgrade of bookings to better available tables where the better tables are not forecasted or predicted including late bookings and walk-in to be required;
3. The allocation of bookings based on a customer's CRM history or social media profile; and/or
4. The allocation of bookings based on a First In Best Seat (“FIBS”) system on the basis that the earliest request received should receive priority, as it is likely that such a booking may represent a significant special occasion like a wedding anniversary, special birthday or occasion as compared to a last minute booking where expectations could be less or would be less on the basis that it is a last minute booking.

In one embodiment of the system the application of the following methodology:

a. allocating the received booking request to the requested table;
b. allocating the received booking request to the requested table by firstly identifying one or more requestors associated with the booking request, and using the identity of the one or more requestors to retrieve constraint information including a requestor ranking relative to other requestors, whereby the booking request is allocated based on the requestor ranking;
c. where a requested table is already allocated to a previous booking request, determining the identity of the one or more requestors associated with the booking request and using the identity of the one or more requestors to retrieve constraint information including a requestor ranking relative to the previous booking requestors, and if the ranking of the requestor is higher than the ranking of the previous booking requestor, reallocating the at least one previously allocated booking request to a different table to allow the received booking request to be allocated to the requested booked table;
d. upon requiring a reallocation of at least one booking to accommodate a received booking request, reallocating the at least one previously allocated booking request by allocating the booking request of the largest size first and reallocating all other booking requests in descending order of size;
e. upon requiring a reallocation of at least one booking to accommodate a received booking request, determining a booking size metric of the received booking and each of the allocated bookings by calculating a size metric which utilises the number of persons that comprise the booking request and the service time duration for the booking request as inputs, and utilising the size metric to reallocate all bookings in order from the largest size metric booking to the smallest size metric booking;
f. determining a difficulty metric utilising the size metric and a peak period seating time value to determine a difficulty measure, the difficulty measure representing a theoretical measure of the relative difficulty in allocating the booking request, whereby booking requests are ranked from most difficult to least difficult and allocated in descending order from most difficult to least difficult;
g. determining sub-service periods within a service period, and for all booking requests that fall within the service period, firstly allocating all booking requests that fall across one or more sub-service periods in order of descending size, and subsequently allocating all booking requests that do not fall across the one or more sub-service periods in order of descending size;
h. utilising constraint information to determine a difficulty measure, the difficulty measure being representative of the relative difficulty of allocating a booking request, whereby bookings are allocated in descending order of difficulty;
i. reallocating at least one previously allocated booking request to optimise the number of bookings within each of the one or more spaces;
j. reallocating at least one previously allocated booking whereby bookings of identical or similar size are clustered, in both physical proximity and chronological proximity;
k. reallocating at least one previously allocated booking whereby the total time that the each table or table combination remains unused between bookings during a single service period is minimised;
l. reallocating at least one previously allocated booking to cluster bookings such that physically adjacent tables have similar start times;
m. reallocating at least one previously allocated booking such that physically adjacent tables have similar finish times;
n. reallocating at least one previously allocated booking so that smaller size bookings are physically clustered adjacent to larger size bookings;
o. Reallocating at least one previously allocated booking such that a previously joined table for an earlier booking in a service period is reutilised for a later booking in the service period;
p. reallocating at least one previously allocated booking such that the at least one booking is allocated in a manner where a minimal number of tables are joined or split to allocate the booking;
q. reallocating at least one previously allocated booking such that the total of bookings within a service period are arranged in a manner that requires the least possible number of table movements during the service period;
r. allocating at least one potentially conflicting booking to the smallest fitting table irrespective of availability, and where a conflicting booking is generated, reallocating the previously allocated booking as a result of the newly created conflicting allocation;
s. reallocating at least one previously allocated booking whereby an empty table is retained between one or more booked table;
t. utilising constraint information to reallocate all bookings from the highest ranked available table in a descending order of rank;
u. reallocating at least one previously allocated booking whereby the ranking of the booking requestor determines the table allocated;
v. reallocating at least one previously allocated booking utilising one or more qualitative constraints derived from information associated with the booking requestor including but not limited to a stated occasion associated with the booking, a menu or courses selected by the requestor, the courses selected by the requestor, ancillary products selected by the requestor and the date of the booking; and
w. reallocating all bookings to one or more different table solution sets to determine whether at least one of the one or more different table solution sets results in a more optimal outcome, and if so, selecting the at least one of the one or more different table solution sets that results in the more optimal outcome.

In one embodiment, the optimisation and prioritisation model is linked to a CRM and, or third party websites and capable of differentiating between booking requests where there are identical or similar bookings to allocate the higher ranked table to the higher ranked, more regular customers, or potentially more beneficial customers to the restaurant utilising information from at least one of internal or third party databases of information, wherein the identity of the customer making the booking is utilised in conjunction with the database information. The CRM may include any relevant information, such as:

1. Customer membership levels;
2. Customer rankings within each membership level;
3. Customer priority seating levels (“VIP” and “SVIP”);
4. Customer seating preferences including, space, tables, chairs;
5. Customer constraint preferences as used in the various algorithms;
6. Customer information including individual item selections from previous visits over and above any booking information for the table through the use of position numbers with the booking; and/or
7. Waiter and staff inputted information concerning details and preferences of the customer with reference to the booking allocation algorithm.

In one embodiment, all locations, sections, subspaces and spaces are allocated a dynamic identifier such that all tables are sequentially numbered in a consistent manner irrespective of the relative reconfiguration of the tables as more bookings are taken so their usage or usage of the area can be monitored and compile an area or table preference rating which can be used for the dynamic pricing of tables.

In one embodiment, the constraint information can determine and make available a plurality of booking times and capacities such that a user may select specific tables, locations and/or seating arrangements from the available tables, locations and/or seating arrangements with or without the requirement of an additional payment.

In one embodiment, the constraint information is arranged to vary the available menu and courses to a customer dependent on group size, or the day or time of an available booking, in a manner which optimises available resources within a restaurant.

In one embodiment, the constraint information is arranged to vary the party sizes that it will accept at different times, such that inefficient booking sizes such as 1, 3 or 5 which result in tables with unutilised seats being eliminated from peak restaurant booking and demand times.

In one embodiment, a user can select any one of a preferred table, selecting booking time, time duration at the table and payment of a further amount.

In one embodiment, the computing system is arranged to communicate, via a communications network, with supplier servers (the suppliers being arranged to provide third party services), wherein a request to utilise a third party service received from a user is autonomously relayed to the third party site. For example, the database of the embodiment may include information regarding florists, chocolate shops, guitarists, magicians and entertainers, to provide a listing of the additional services that a diner may request through their booking in addition to any ad hoc requests made by the diner upon booking.

In one embodiment, a customer can create a tailored and personalised dining experience where they can select any number of personalised services such as, their personal waiter, a specific flower arrangement on the table or a bunch of flowers for their guest, a bottle of champagne next to their table to be opened on their arrival, a specific food and beverage menu or specific food and beverage items including the provision of a specific vintage or rare bottle of wine, a guitarist or other entertainer during their meal or a present on departure to remember the evening, inviting guests, creating place cards and allocating guests to table position numbers.

In more detail, in the embodiment described above, the computing system is arranged to manage and communicate bespoke and personalised dining experience selections whereby the system automatically places orders with suppliers, confirmations, compiles run sheets and information for the restaurant's Head Chef and Restaurant Manager and Restaurant office staff of the requirements and post the information on the restaurants diary, and issue invoices and receive payments.

In one embodiment, there is further provided a self-seating app or widget showing the allocated table location within the restaurant floor plan, together with the table number and the position numbers and location of each individual guest including the ability to print name cards for use on the table.

In one embodiment, the optimisation or prioritisation algorithm utilises the processor to determine the revenue potential for a particular combination of menu, group size and date/time of a booking, wherein the artificial intelligence algorithm dynamically varies the booking options offered to a customer to control the capacity offered to optimise revenue.

In one embodiment, the system is arranged to monitor the user request for any particular table, section, subspace, space, class or venue by at least one of the date, service, time, occasion, group size, or other relevant parameter to determine the appropriateness of dynamic pricing changes for the table, area, subarea, section or class or changes to other parts of the venue to increase efficiency.

In one embodiment, the system is arranged to utilise information regarding the historical performance of one or more spaces, subspaces, sections or classes to improve the performance of one or more other spaces, subspaces, sections or classes. In other words, the system utilises an algorithm that utilises a number of types of information relevant to entire space and applies the information gained from one section of the restaurant to better organise another area of the restaurant. In colloquial terms, the algorithm takes a “holistic” overview of the restaurant as a whole before optimising a space, subspace, section, or class.

In one embodiment, the system is arranged to execute a simulation using estimated booking patterns or historical booking patterns to determine an optimal restaurant layout. The layout may include selecting the most appropriate table sizes and furniture, quantities of different table sizes and furniture to purchase, flexible seating areas versus fixed seating areas, different combinations of areas, subareas and sections, different classes to determine an optimised restaurant furniture layout so as to assist in the management of the restaurant, the set-up of the restaurant or the financial projections and planning of the restaurant.

In one embodiment, the system may also optimise one or more constraints, the iterative allocation of bookings and/or defining of a venue into spaces, subspaces, sections, classes within the restaurant the offering of different menus in different situations and at different times, the allocation of SVIP's to their preferred table and the rating of tables. Such an embodiment allows customers to select their preferred table, offering different amounts of time to different menus with different courses. In other words, the constraint aspect of the broader inventive concept may be combined with a static linear combinatorial priority list to provide a level of optimisation and automation, while not utilising a dynamic table allocation algorithm.

In one embodiment, the user interface is arranged, in response to restraint information provided by the user, to provide additional restraint information to the user, wherein the system provides an interface to allow the user to accept the additional restraint information or alter their request.

In one embodiment, the database includes menu constraint information regarding menus available, the menu constraint being dependent on the time period constraint information provided by the user, whereby the computing system provides a choice to the user to accept the additional restraint information or the user alters their request dependent on the menu constraint information.

In one embodiment, the user interface is arranged to permit a user to search for the availability for two different spaces in a venue, and if availability is found in both spaces to book and pay for both spaces simultaneously. For example, a booking could be made for two stools at 7 pm at the bar for drinks and then a table for 2 at 7:30 pm in the main dining room for dinner.

In one embodiment, the user interface is arranged to permit the user to search two different venues for availability and if availability is found at both venues the user books and pays for both venues simultaneously. For example, one venue may be a theatre or show and the other venue is a restaurant.

In one embodiment, the optimised and/or prioritised allocation instruction set is saved in the database and provided as a diagrammatic representation within a detailed representation of the floor plan. In a specific embodiment, any new or additional tables or furniture added into a space, subspace, section, class or venue are highlighted so that the restaurant manager may easily visualise and understand the type, quantum, and location of the additional furniture as compared to the standard floor plan layout, number of tables and location.

The claimed invention defines a properly constructed “three dimensional volumetric relationship” using the floor plan (two dimensions) and time (as the third dimension). As such, there are no requirements to use scheduling software techniques to incorporate time within the claimed invention.

In one embodiment, the optimised and/or prioritised allocation set saved in the data base and provided as a diagrammatic representation within a detailed representation of the floor plan changes dynamically over time, such that the representation of the table allocation is layered in time with a notation as to how many times each table will be used during service. In other words, the floor plan displayed on the user interface is a true “live” representation of the table plan at any point in time during a service with the representation of the tables being rearranged with the correct table numbers and gaps between tables. This feature also allows restaurant staff or anyone looking at the floor plan to easily identify the location of a table or easily understand how to reset and reposition tables.

In one embodiment, the system is arranged to autonomously communicate to a third party the requirement to provide additional furniture or other items required for a service.

In another embodiment, there is provided a payment module arranged to provide a pre-payment interface arranged to discriminate between booking requests wherein pre-payment obligations are tailored to the user's booking request. Such a module ensures that, where necessary, a requestor making a booking request has a greater commitment to ensuring they turn up, minimising “no-shows” and increasing restaurant revenue and profitability in the allocation of a booking to a space, subspace, section, class, table or table combination.

In another embodiment, the system utilises information in the database, such as a person's CRM ranking, as a constraint to make a final determination as to whether a person is required to meet the pre-payment criteria to secure the booking. Such a system provides greater recognition to loyal customers and assists in the process of displaying mutual trust and respect for loyal patronage.

In one embodiment, the algorithm interrogates the data base to locate unbooked periods of time longer than the minimum time required to consume a one course menu to match an appropriate menu or menu(s) to the periods of time, wherein the system offers the located booking times and booking durations to users at a discounted cost. This allows the system to autonomously “backfill” unused time slots, which increases restaurant revenue while minimising discounts offered for other non-constrained bookings.

In one embodiment, the data base is interrogated to find periods of time that contain short lead time unallocated space, sub-space, section, tables or chairs and offering such space at a discount in order to create and have a standby list of customers.

In one embodiment, the system is arranged to calculate and collect information concerning the duration times of customers and associating the duration times with relevant constraint information. The constraint information may include menu, menu courses, time of booking, day of booking, occasion, and/or group size. The collected information is used to provide recommendations or autonomously adjust booking duration times allowed for different areas, subareas, sections or classes at different times, menus and courses offered.

In one embodiment, the seating allocation of a restaurant is analysed by comparing the hypothetical actions which would have been taken by a system in accordance with the invention, to actions taken by a manual intervention, to determine whether the autonomous action or the manual intervention provides or provided a more favourable outcome using a customer's CRM or social media ranking.

In one embodiment, restaurant capacity is calculated as the product of the tables that are capable of incorporation into the space including additional tables as they would have been included by the autonomous use of the allocation algorithms and the number of chairs and the number of hours that the restaurant is open for service. This hypothetical calculated capacity is utilised as a benchmark and used to compare to real life performance (specifically against manual interventions performed by a member of staff) to evaluate whether the manual intervention produces a more desirable result. If so, the algorithm autonomously adjusts the algorithm and allocation process.

In one embodiment, restaurant utilisation is calculated as the product of the total number of guests that can be seated by the system and algorithm including the allocation and use of additional tables and the number of hours that users were seated. In other words, the metric is the product of the total chairs the system managed to incorporate into the floor plan multiplied by the hours the restaurant was open for a service or other defined period. This is a more useful metric as it represents a true utilisation value.

In one embodiment, the revenue yield is calculated as the product of the actual revenue received for a period divided by the revenue that could have been received if all items had been sold at their full recommended retail plus the revenue at the full recommended retail price of any complimentary items. For this calculation to be undertaken a full complete, itemised, detailed list of all products supplied to customers and other information contained in a restaurant point of sale system and other relevant information from other systems is integrated and recorded.

In one embodiment, the efficiency of area space, subspace, section, class or restaurant is the product of the capacity utilisation and the revenue yield.

In one embodiment, an optimal capacity utilisation may be calculated by varying defined fixed and flexible seating areas within the restaurant to determine an optimum ratio of fixed versus flexible seating areas. In one embodiment, the system can recommend changes to areas, menus, courses, times, and/or group sizes to provide a more optimised solution. In the context of the embodiment described, optimum is defined according to goals set by the restaurant and by the inherent limitations of the restaurant, such as the table sizes and table types available within the fixed and flexible seating spaces, subspaces, sections, classes or within the restaurant.

In more detail, resource constraints such as desired customer service standards may be calculated by inputting wait staff to customer ratios, staff set-up times for different booking levels, bar staff to customer ratios, food runner to staff ratios, reception staff to customer ratios by booking times, kitchen to customer ratios based on menus offered for a service and/or if food is pre-ordered the input of more specific kitchen to staff ratios by space, subspace, section, or class while also considering additional personalised customer booking requests and restaurant set-up requirements including allowing for late bookings and walk-ins in combination with the timing of customer menus and arrival times. This comprehensive input of data allows the system to provide detailed rosters which are created and communicated to staff.

In one embodiment, the user interface allows at least one remote user to input into the data base information and constraints regarding a plurality of events that a restaurant may undertake, participate in or which may have an impact on the demand for the restaurants services. The information and constraints provide input regarding the expected impact of such an event and may include, for example, the number of invited guests or the number of the people who may be expected to attend the events. The event information and constraints are as an input by the forecasting algorithm to determine forecasted demand, which in turn is utilised to determine a set of constraints to apply to the capacity allocations, such as determining appropriate menus, courses, booking times, booking durations, staffing and other resource requirements.

In one embodiment, additional information (such as forecasted weather and known future events) is provided to the algorithm to predict future demand by space, subspace, section, class or for the restaurant. The future predicted demand is used to adjust the options offered to customers. In other words, menus, booking times, booking durations, and the relative probability of gaining additional revenue from the charging of different fees such as from extending booking times, are calculated. In turn, the system may then allocate bookings and/or limit bookings. For example, if the probability of walk-in customers is high, some tables may be reserved for walk-in customers, who may then be charged at a premium. Alternatively, if the probability of walk-in customers is low, a discount may be applied to customers who book, in order to attract booking customers. That is, the system autonomously optimises booking constraints to optimise revenue for the restaurant.

In summary, previous utilisation patterns and other constraints may be utilised to forecast demand, revenue, and to autonomously adjust the capacity and constraints provided by the system to a remote user.

In one embodiment, the associated constraint information includes an incentive, the incentive being communicated to the booking requester.

In one embodiment, the allocation algorithm applies a differential pricing model dependent on the venue constraint information and the requester constraint information.

In one embodiment, the one or more potential booking allocations are determined by calculating the optimal revenue yield of a plurality of potential booking allocations and selecting one or more of the plurality of potential booking allocations on the basis of a revenue yield threshold, wherein the selected one or more potential booking allocations are communicated to the requestor.

In one embodiment, the transfer of information from the reservations and allocation system to other systems, such as, the labour and roster system, the food ordering and purchasing system and the kitchen printing system is autonomous.

In one embodiment, the reservations dairy is capable of autonomously processing any type of booking, including individual bookings and function bookings. This is achieved, at the user interface, by providing an integrated booking widget and/or booking app.

In one embodiment, the app or widget includes a self-seating function which is capable of displaying and directing a user to a table by presenting the user with an exact representation of the table and floor plan of the restaurant. This may be achieved by a combination of any one or more types of information display, including a location map including a restaurant floor plan, a table number, position numbers of individual guests and the ability to autonomously print name cards for use on the table, or display electronic name cards in situations where electronic displays are available at the table.

In one embodiment, individual customer information is tracked by table position number so that the restaurant CRM contains data specific to the customer. The collection of customer specific data allows for the tailoring of a customer's future visits.

In one embodiment, the reservations diary allows for multi-venues and multi-time zones within a single diary. In other words, customer facing diaries and internal diaries (which may operate in different manners) are automatically reconciled to avoid the need for any transfer of information from one diary to another.

In more detail, there may be provided a multi calendar that permits additional user defined calendars to be created for reporting and management purposes. The user defined calendars may have a different start and end date to the bookings calendar, a different number of months and different start and end dates for each user defined month (or period), may commence on any day of the week, and has user defined reference points so that equivalent time periods in previously defined years, months or weeks maybe reconciled against current or future defined years, months or weeks.

In one embodiment, the performance module calculates and uses the measures of available seat hours to measure capacity, actual seat hours to measure usage, revenue yield to measure the actual revenue received against the revenue that could have been received had all items sold and complimentary items given been charged at their full recommended retail price and efficiency as the product of capacity utilisation by the revenue yield.

In one embodiment, a home delivery diary is integrated into the system and is arranged to receive on-line home delivery orders.

In one embodiment, a gift certificate system is integrated into the system and is arranged to issue gift certificates.

In one embodiment, a gift certificate module is provided, the payment module is arranged to accept gift certificates as a form of pre-payment. The gift certificate may be utilised as a deposit, part payment or full payment for a booking.

In one embodiment, a kitchen interface is integrated, wherein orders are provided to the kitchen for seated customers or home delivery orders directly to the kitchen, wherein constraint information is provided to estimate cooking times and delivery times to thereby prioritise orders and optionally communicate the estimated times to the restaurant manager and/or the customer.

In one embodiment, there is provided an autonomous, integrated restaurant management system using the online booking system and the diary and data base as the core central system. The restaurant management system may interface electronically with ancillary systems in order to receive or provide information. Notwithstanding the requirement to source or provide data to other external systems, the restaurant management system, in an embodiment, provides an integrated system by providing the following functionality:

1. A CRM for the correct allocation and prioritisation of bookings;
2. A database of evolving operational constraints for the correct allocation and prioritisation of bookings;
3. A module to provide and redeem gift cards;
4. A POS system for the transfer of the dynamic and changing floor plans and table numbers;
5. A POS system for transfer of any pre-orders or menu selections;
6. A POS system and/or kitchen printer for the provision of pre-orders directly to the kitchen;
7. A payment gateway for the collection and processing of payments;
8. A home delivery ordering module for receiving and processing home delivery orders, including the autonomous management of kitchen priorities and workload;
9. An integrated booking module capable of receiving and processing both individual and function bookings;
10. Integration with third party purchasing modules to co-ordinate personalisation considerations for the ability to provide dynamic reporting, forecasting and yield management information to a requestor of the provision of dynamically changing menus based on available times and resource constraints for customers to review, pre-order, or order at the restaurant; and/or
11. A self-seating capability which may be deployed to kiosks, in-restaurant devices and/or user devices which provides a floor plan showing the table allocated on a floor plan as it would be on their arrival.

In one embodiment, there is provided an interface that allows a customer to tailor a function space to a customer's requirements and provide payment autonomously, wherein all actions required to prepare the function space are created autonomously, including the creation of run sheets, table numbers, AV requirements, the placement of orders with suppliers and the organisation of staffing requirements.

In one embodiment, the interface utilises feedback information from the user, and optionally, historical data, to provide intuitive suggestions to enhance a function experience and/or to offer an alternative when the first preference is not available. This may include capturing information such as occasion type, experience sought, and theme of event, group size, budget or other constraints.

In one embodiment food menus, food menu packages and beverages and beverage packages offered to booking requests are autonomously selected in response to information received regarding the occasion, theme, and style of event and group size.

In one embodiment, the interface is arranged to provide a floor plan to the user whereby the floor plan dynamically alters depending on the booking information provided. This may include appropriate table configurations, decorations, audio-visual equipment.

In one embodiment, the function booking system recognises, evaluates and prices all items selected and placed on the floor plan together with any other selection to provide the user an itemised quote and price for the function they have selected, designed and personalised, whereby the user can make further changes, make a tentative booking, be provided a reference number and be able to make further changes in the future up until which time a deposit would need to be paid to secure the function room or they would lose their tentative booking.

In one embodiment, if a subsequent user wish to book a space where a previous user has a tentative booking on a space the user with the tentative booking receives an autonomous communication requesting that they confirm the tentative booking within a defined period of time.

Embodiments of the system, as described above, allows for the autonomous placement of orders, invoicing, monitoring and management of the entire delivery process for a confirmed function.

In one embodiment, position numbers are allocated to a table by the system and a user may utilise the interface to allocate guests against the defined position numbers. Once guests have been allocated to position numbers, the system may autonomously contact the guests and invite the guests to utilise the interface to pre-order and, if appropriate, to pre-pay for the guest's share of the cost of a booking or of the function. Name cards or place cards can also be selected as an option to be printed and placed on the table(s) at a user's request.

In a further aspect, there is provided a computing system for optimising the use of space in a venue, comprising: a user interface providing module arranged to provide a user interface to at least one remote user via a communications network, a user input receiving module arranged to receive at least one request to reserve a space for a period of time within the venue from the at least one remote user via the communications network, a negotiation module in communication with a processor and arranged to receive the at least one request and communicate with a database to retrieve constraint information regarding the venue and determine whether the at least one request can be accepted, and if not, utilise the processor to retrieve information regarding the other requests for spaces and propose at least one alternative request to the user via the user interface, wherein if the at least one alternative request is accepted by the user, the at least one alternative request is saved in the database.

In one embodiment of the system an algorithm interrogates the database to determine what tables, booking times and booking durations have not been booked and make available for specific promotions. In a further embodiment the menus pricing and other terms and conditions for each offer can be determined by the system by matching the demand profile for these available tables, times and durations with constraints and different promotional packages set up by the venue.

In one embodiment of the system different promotional packages can be set up for which the algorithm can then select from to provide an incentive to accept alternate booking details. The promotional packages that can be set-up include: a percentage discount on the whole bill or part of the bill, a percentage discount only on food or part of the food, a percentage discount only on beverages or part of the beverages, the provision of various complementary items including a complimentary glass of wine and a complimentary dessert. Further, the specific circumstances to which these promotional packages can apply by service, by day, by date. For example, the maximum promotional benefit on a Monday may be greater than a Saturday, and the maximum potential benefit at a non-peak time may be greater than a peak time.

In one embodiment of the system the provision of an incentive or promotional benefit for a customer to accept an alternate time offered, or alternate booking duration or more stringent terms and conditions.

In one embodiment of the system a person who has already made a booking is able to log in and change the details of their booking.

In one embodiment of the system permit the booking requestor to determine the seating position of their guests.

In one embodiment of the system permit the booking requestor to invite their guests to pre-order and part pay or pre-pay for their selections.

The negotiation module may propose at least one alternative request using past alternative request data retrieved by the processor from the database.

The past alternative request data may include the frequency of the acceptance of the at least one alternative request by the user.

The negotiation module may be biased to propose at least one alternative request based on the relative frequency of the acceptance of the at least one alternative request by the user when compared to other alternative requests saved in the database.

The negotiation module may provide at least one alternative request until such time as the request is abandoned by the user.

The at least one alternative request may include an autonomously generated incentive to provide an incentive to the user to accept the at least one alternative request.

The incentive may include at least one of a good and service related to the at least one alternative request.

In one embodiment the use of artificial intelligence to interact and better tailor and optimise the quantitative and qualitative constraints to achieve the outcomes based on the strategy of the venue while best meeting the needs of the customer. The venues can include function spaces, event spaces, workspaces hotel and accommodation.

In another aspect, there is provided a computing system for optimising the use of space in a venue, comprising: a user interface providing module arranged to provide a user interface to at least one remote user via a communications network, a user input receiving module arranged to receive at least one request to reserve a space for a period of time within the venue from the at least one remote user via the communications network, a negotiation module in communication with a processor and arranged to receive the at least one request and communicate with a database to retrieve constraint information regarding the venue and determine whether the at least one request can be accepted, and if not, utilise the processor to retrieve information regarding the other requests for spaces and propose at least one alternative request to the user via the user interface, wherein if the at least one alternative request is accepted by the user, the at least one alternative request is saved in the database.

The negotiation module may propose at least one alternative request using past alternative request data retrieved by the processor from the database.

The past alternative request data may include the frequency of the acceptance of the at least one alternative request by the user.

The negotiation module may be biased to propose at least one alternative request based on the relative frequency of the acceptance of the at least one alternative request by the user when compared to other alternative requests saved in the database.

The negotiation module may provide at least one alternative request until such time as the request is abandoned by the user.

The at least one alternative request may include an autonomously generated incentive to provide an incentive to the user to accept the at least one alternative request.

The incentive may include at least one of a good and service related to the at least one alternative request.

In another aspect, there is provided a computer system for optimising the use of a restaurant, comprising: a database arranged to provide historical and live data regarding the use of the resources of a restaurant, an input module arranged to receive information regarding the actual usable resources at any given time, an optimisation module in communication with a processor and arranged to receive the at least one request and communicate with the database to receive the historical and live data and the actual usable resource data, wherein the data is analysed utilising a yield determination algorithm to determine the relative optimal use of the usable restaurant resource. The optimisation module may provide information regarding one or more parameters that may be optimised to increase the yield of the restaurant.

The historical data may be utilised by the algorithm to forecast future demand.

The database may include information from other restaurants, to provide comparison data.

The historical data may be utilised to calculate resource requirements.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1a is an example computing system on which a method and/or a computer program may be operated, in accordance with an embodiment of the invention;

FIG. 1b is an example of a flowchart illustrating a computer system upon which a computer enabled method may be operated, in accordance with an embodiment of the invention;

FIGS. 2a-2e are flowcharts illustrating a computer enabled method for a booking process in accordance with an embodiment of the invention;

FIGS. 2f-2g are flowcharts illustrating a computer enabled method for a booking process in accordance with an embodiment of the prior art;

FIGS. 3a, 3c, 3d, 3e and 3f are illustrations of a volumetric (three-dimensional) framework for providing a complex product and service in accordance with an embodiment of the invention;

FIG. 3b is an illustration of a volumetric (three-dimensional) framework for providing a complex product and service in accordance with an embodiment of the invention, as compared to an embodiment of the prior art; and

FIGS. 3g, 3h and 3i are illustrations of a framework for providing a product and service in accordance with an embodiment of the prior art.

### DETAILED DESCRIPTION OF PREFERRED EMBODIMENTS

The present invention relates generally to a computing system, method, and computer program for managing a venue with one or more spaces by utilising an Artificial Intelligence engine which is integrated into a booking, allocation and management system to provide an autonomous system for managing a restaurant (or another venue that requires a complex delivery of products and services, including the allocation of a temporary space and/or furniture/equipment). In one embodiment which is described in more detail herein below, the invention is directed to a computing system, computer enabled method, and computer program which includes and one or more modules, the modules including algorithms arranged to utilise artificial intelligence which utilises venue constraint information regarding one or more aspects of the space and also requestor constraint information regarding one or more aspects of the booking request, and optimises both quantitative and qualitative outcomes for both the booking requestor and the venue.

The qualitative and quantitative outcomes may include improving the ambiance of the venue in one or more spaces, optimising use of the space, allowing booking requestors to request specific portions (e.g. tables or seating arrangements) or be allocated to a specific portion as a priority, offer and offering dynamic pricing and dynamic differentiated products and services. In this manner, the algorithm “mimics” the intelligence provided by a maitre de' or restaurant manager in a manner that a conventional electronic booking system cannot mimic.

The algorithm provides true yield management, booking requestor self-management and an integrated and autonomous system. In one embodiment, the venue is a restaurant and the allocated portion may be a table, a seat at a bar, or any other seating arrangement.

In more detail, one aspect of the embodiment described herein provides a computing system for optimising the use of one or more spaces in a venue, which includes a user interface module arranged to provide a user interface to at least one remote user via a communications network. The embodiment further comprises a user input receiving module arranged to receive at least one request to reserve a space within the venue from the at least one remote user via the communications network.

The embodiment also comprises an allocation module which is in communication with a processor. The allocation module includes an intelligent algorithm that mimics the thought processes of a person who would perform the role of allocating tables to bookings. In technical terms, the embodiment is arranged to receive the at least one request and communicate with a database via a processor to determine whether other requests for spaces have been made by other remote users.

If other requests for spaces have been made by other booking requestors, the allocation module either on receipt of a request or upon the activation of a trigger event utilises the processor to retrieve information regarding the other requests for the one or more spaces and combines the at least one request with the other requests to form a pool of requests, retrieve constraint information regarding the venue, and iteratively allocate all requests from the pool of requests utilising the constraint information to produce an optimised space allocation instruction set, wherein the optimised space allocation instruction set is saved in the database and provided by a space allocation user interface to one or more users associated with the venue.

Embodiments of the present invention use a knowledge of the dimensions of the space and what the Applicant has dubbed a “volumetric” algorithm to optimise capacity and revenue within a single venue or a multi-venue restaurant environment that can include diverse operations such as fine dining, casual dining, cafes and cabaret shows. The system includes an artificial intelligence algorithm which avoids the inherent constraints in prior art solutions. All known prior art solutions are based on allocating booking requests to a set list of tables and table combinations using simple look-up formulas. In a static allocation model, allocation consists simply of finding the first available and suitable table in the set list. In so called “dynamic” solutions, combinatorial constraint programming or so-called “dynamic” programming is used to allocate each booking request to a table or table combination. Combinatorial constraint programming and dynamic programming, while theoretically applicable to the problem of allocating bookings to tables, fails to provide a practical solution, as neither technique is computationally efficient and both techniques are unable to optimise for qualitative outcomes.

By defining the problem as the “optimisation of the use of a space” embodiments of the invention provide a fundamentally different conceptualisation of the problem to be addressed, in that, in optimising a restaurant, there are many more considerations than the random allocation of booking requests to predefined tables and table combinations. To provide a specific example, a well-run restaurant, if it is to maximise yield and grow customer loyalty, has to determine how to best use the space available, which includes the ability to allocate booking requests to tables in a manner that takes into account other aspects of the dining experience, such as the ambiance within the restaurant, the allocation of a person to their preferred location or table, the distance between tables (which impacts on desirable qualities during the dining experience such as privacy), the ability of the restaurant to offer different menus at different times and at different prices to the same or different areas within a restaurant, allowing diners to extend meal period times without causing strain on available resources or conflicts with other bookings, offering different menus, offering personalisation to achieve the individual requirements and strategies of different venues and restaurants in a way that also better meets customers' requirements and demands. As such, the “volumetric” algorithm described and defined herein below is an artificial intelligence that utilises quantitative and qualitative criteria to provide an integrated and autonomous restaurant management system.

In the following description of an embodiment, specific terms will be used to broadly define particular features or aspects of the inventive concept or the information utilised to allocate a booking request, within the context of a specific example embodiment, namely the allocation of bookings in a restaurant.

Therefore, for the avoidance of doubt, in the embodiment described, the term “booking requestor” is a broader term for a person or entity interacting with the embodiment to make a booking request. Once a booking request is allocated, the booking requestor becomes a “customer”, “patron” or “diner” of the venue. In the example embodiment, the term “restaurant” is utilised as a proxy for the term “venue”, insofar as a restaurant is a practical example of a venue. The terms “space”, “sub-space” and “section” refer to specific delineated areas of the venue. The term “allocated portion” refers to the specific area within the venue that is allocated to the booking requestor. In the “real world” example embodiment described herein, the “allocated portion” may be a table, a series of tables, a seat (such as a chair or a bar stool) or may simply be a physical space, devoid of specific furniture. Therefore, where reference is made to customer being allocated a table, table combination, a seat, etc., the reader is to interpret this reference as a specific example of a booking requestor being allocated an “allocated portion”.

The preferred embodiment detailed below has been described under various headings for ease of reference by the reader and to provide a logical deconstruction of the features and aspects that comprise the claimed invention. However, it will be understood that the headings are provided merely as a guide to the reader, and no gloss should be taken from the headings to limit the embodiments or the broader inventive concept described herein.

In addition, while the description provided herein below refers to aspects of the inventive concept that may be considered abstract in nature, such aspects are described in the abstract for the purpose of providing context to the technical implementation and the technical aspects of the claimed invention and no gloss is to be taken from the abstract description of underlying concepts to inherently limit the technical nature and scope of the invention. The Applicant makes no claim over the abstract concepts described herein, only to the inherently technical implementation as claimed in the claims of the present specification.

### The Computing System

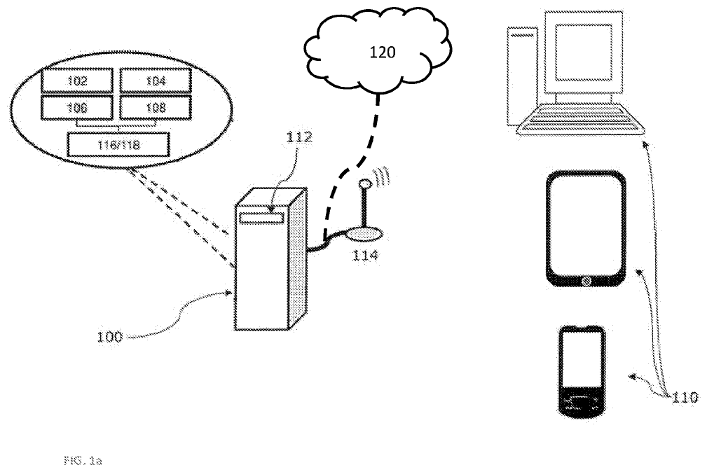

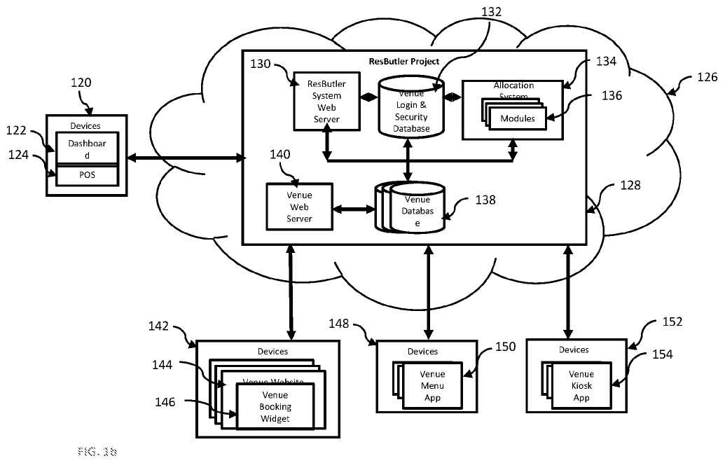

One embodiment of the computing system is shown at FIG. 1a.

In FIG. 1a there is shown a schematic diagram of a computing system, which in this embodiment is a computing system 100 suitable for use with an embodiment of the present invention. The computing system 100 may be used to execute application and/or system services such as a computer program and an interface in accordance with an embodiment of the present invention.

With reference to FIG. 1a, the computing system 100 may comprise suitable components necessary to receive, store and execute appropriate computer instructions. The components may include a processor 102, read only memory (ROM) 104, random access memory (RAM) 106, an input/output devices such as disc drives 108, remote or connected mobile devices 110 (such as computers, smartphones or tablets and the like), and one or more communications link(s) 114 including internet links to other applications, websites and system services including Internet cloud services 120.

The computing system 100 includes instructions that may be installed in ROM 104, RAM 106 or disc drives 112 and may be executed by the processor 102. There may be provided a plurality of communication links 114 which may variously connect to one or more user devices 110, such as computers, smartphones or tablets, wherein the one or more user devices have a user interface for interacting with user by collecting and displaying data or information using the conventional means provided by such devices. At least one of a plurality of communications link 114 may be connected to an external computing network through a telecommunications network, including Internet cloud services 120.

In one particular embodiment the device may include a database 116 which may reside on the storage device 112. It will be understood that the database may reside on any suitable storage device, which may encompass solid state drives, hard disc drives, optical drives or magnetic tape drives. The database 116 may reside on a single physical storage device or may be spread across multiple storage devices, either locally or remotely.

The computing system 100 includes a suitable operating system 118 which may also reside on a storage device or in the ROM of the server 100. The operating system is arranged to interact with the database 116 and with one or more computer programs to cause the server to carry out the steps, functions and/or procedures in accordance with the embodiments of the invention described herein.

The user interface 110 of one or more mobile devices facilitates the collection and display of user data for the computing system 100. The user interface 110 may be a program or website accessed on a computer or mobile device via a communication network, such as the Internet. Alternatively, the user interface 110 may be a widget arranged on a website that may be accessed by a user using a computer or mobile device via a communication network such as the Internet. The user interface 110 may also be provided as a mobile application or “app” present on the user device, such as a tablet or smart phone.

The at least one user interacts with the user interface 110 and may be a first user (also referred to as the “booking requestor”) requesting to use a space in a venue. The at least one user may also include a second user (referred to as the “operator” or “venue operator”), who is associated with the venue and utilizes the optimised space allocation instruction set provided by the allocation module to enable the use of the space by the booking requestor.

The booking requestor interacts with the computing system to make a request. The requestor may make a request for one or more patrons of the venue to use the space in a venue, where the requestor may also be one of the patrons of the venue. That is, a user that interacts with the system is referred (on their own behalf or on behalf of a group of people) is referred to as a booking requestor and the person (or group of people) that will be allocated a table (i.e. attend the venue or restaurant) may be variously referred to as the “patron” or “patrons”, the “customer” or “customers”, the “guest” or “guests” and/or the “diner” or “diners”, or any other term as appropriate for the venue.

An embodiment includes the computer system 100 processing the request and undertaking all subsequent steps in an autonomous manner. Alternatively, in another embodiment, the operator may use one of the user interfaces 110 provided to one or more devices to receive, input, or modify information in order to provide further input to the computer system 100, so that the computing system may process the request and provide instructions to the entity.

In processing the request, the computer system 100 may arrange objects in the space in accordance with the optimised space allocation instruction set. That is, the booking requestor acts as a customer making a request which is to be “serviced” by the operator in accordance with the optimised space allocation instruction set. As may be appreciated by a skilled addressee, there may be any number of remote users and operators who are able to interact with the computing system via the user interface 110 via any number of different devices.

Referring to FIG. 1b there is shown a schematic diagram of the ResButler project. The ResButler application 126 is hosted in a cloud computing environment. The ResButler project 128 includes a web server 130 a venue login and security database 132, an allocation module or system 134 comprising one or more modules or algorithms 136, which connect to a venue database 138 and a venue web server 140. The ResButler project 128 connects with multiple devices 142, 148 and 152. The device 142 is a third-party desktop forward/laptop that is capable of displaying a website rendered by venue web server 140. The venue web server 144 incorporates a venue booking widget 146. Similarly, device 148 is a mobile device such as a smartphone or tablet computing system. The device 148 includes an instance of the menu app 150. Analogously, device 152 is a kiosk including a computing system capable of executing a venue kiosk app 154. The ResButler project 128 also interfaces with a device 120 which is located within the venue. The devices 120 may include a point of sale device (POS) 124 and or a device capable of displaying a dashboard 122 in accordance with an embodiment of the invention.

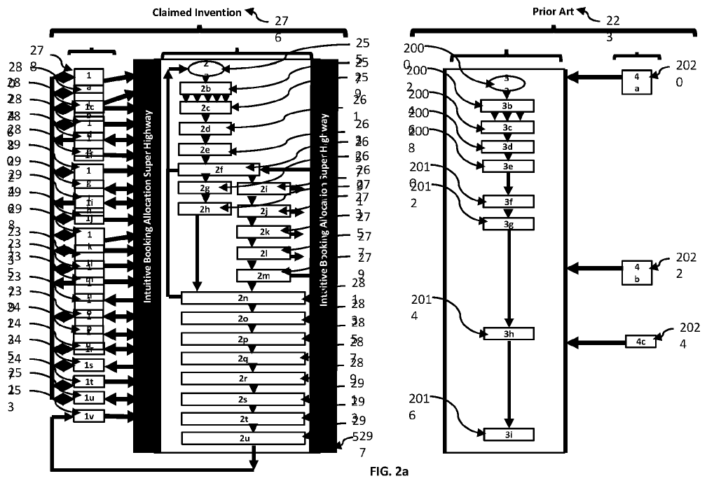

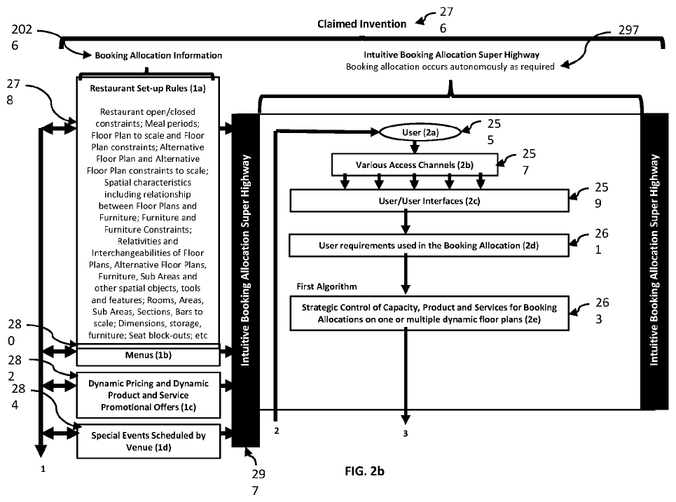

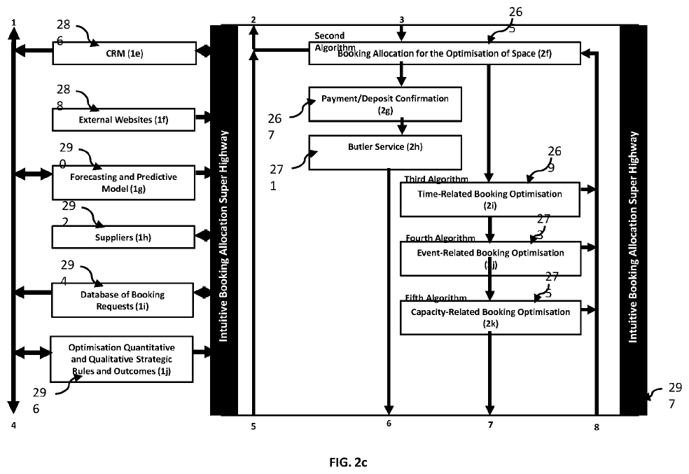

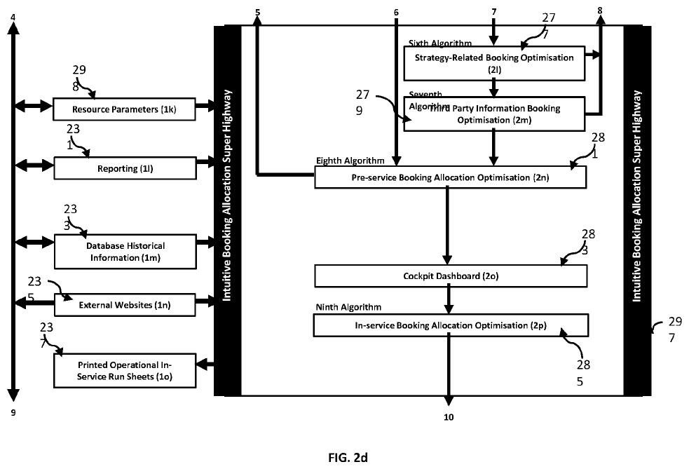

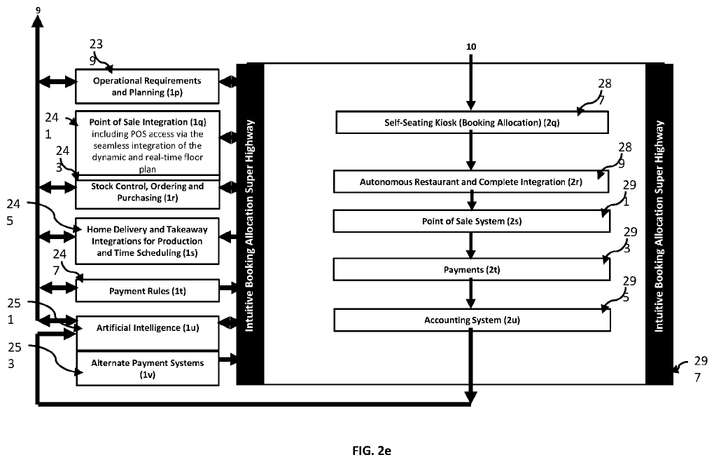

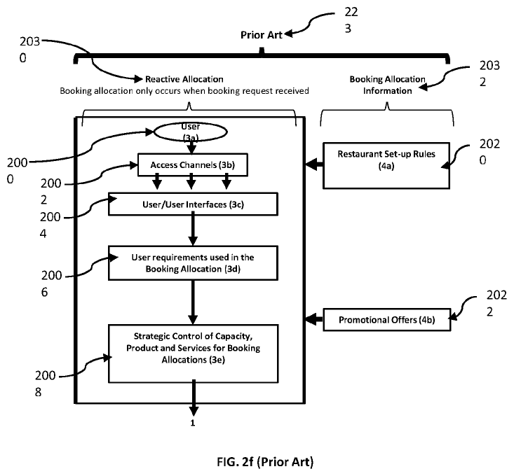

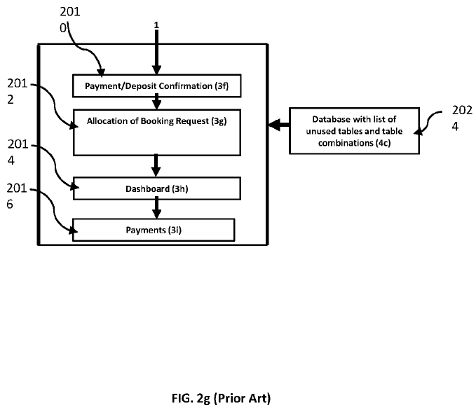

Referring to FIGS. 2a-2g, there is shown a series of flow charts illustrating a comparison between the prior art and a system in accordance with an embodiment of the invention. These figures were previously included in PCT application PCT/AU2018/051168 (and co-pending PCT application PCT/AU2018/051169, PCT/AU2018/051170 and PCT/AU2018/051171) as noted in the background above and also, in the artificial intelligence Australian provisional application AU2019/900128. These figures are also included in the further 11 additional co-pending Australian provisional patent applications lodged on 29 Apr. 2019 which are also related to and support this application. The aforementioned applications are incorporated herein, in their entirety, by reference and are listed below in table 1.

TABLE 1

| Title of related applications | Shorthand |
|---|---|
| A computer-enabled method, system and computer program for providing an | Space |
| intuitive user interface arranged to create a dynamic floor plan utilisable by an | |
| allocation algorithm to perform the task of allocating a space, furniture, | |
| equipment or service | |
| A computer-enabled method, system and computer program for generating a | Widget |
| dynamic user interface for use by a user in the allocation of a space, furniture, | |
| equipment or service | |
| A computer-enabled method, system and computer program for dynamically | Yield Management |
| altering constraints utilised in the management of a space, furniture, equipment | |
| or service | |
| A computer-enabled method, system and computer program for the | POS Transactions |
| management of a multi stage transaction including management of a booking | |
| and service delivery process | |
| A computer-enabled method, system and computer program for providing an | Rosters |
| intuitive user interface and algorithm arranged to create a dynamic roster | |
| utilising an allocation algorithm to perform the task of the allocation of staff to | |
| tasks in a workplace | |
| A computer-enabled method, system and computer program for providing an | Operations |
| intuitive user interface arranged to create a dynamic floor plan utilisable by an | |
| allocation algorithm to perform the task of organising and operating a provision | |
| of a service | |
| A computer-enabled method, system and computer program for providing an | Menus |
| intuitive user interface arranged to create a dynamic product list integrable into | |
| a service provision process to perform the task of delivering a complex service | |
| and managing an associated transaction | |
| A computer-enabled method, system and computer program for providing an | Functions |
| intuitive user interface arranged to create a dynamic floor plan utilisable by an | |
| allocation algorithm to perform the task of managing a function or event | |
| A computer-enabled method, system and computer program for autonomously | Ordering and Allocation |
| allocating and managing a space, furniture, equipment and/or a service via an | Integration |
| electronic device | |
| A computer-enabled method, system and computer program for managing the | Exchange |
| exchange between third parties of service contracts for the provision of a | |
| restaurant booking or other analogous service | |
| A computer-enabled method, system and computer program for monitoring a | Gaming |
| plurality of gaming machines and other games of chance, and providing a | |
| booking and monitoring service for gaming enthusiasts and gaming venues | |
| An autonomous, integrated computer-enabled method, system and computer | Artificial Intelligence |
| program utilising an artificial intelligence engine for dynamic allocation and | (The present application) |
| optimisation of space, furniture, equipment and/or services (AU2019/900128) | |
| PCT/AU2018/051168 (and co-pending PCT application PCT/AU2018/051169, | PCT Applications |
| PCT/AU2018/051170 and PCT/AU2018/051171) | |

Referring to now FIGS. 2a to 2e, there is shown a diagrammatic representation of each of the component parts of the system in accordance with an embodiment of the invention. The following descriptions and information add further matter to the original disclosure in the above-mentioned PCT applications to further particularise the features and embodiments described herein. To the extent that the additional description of features and integers contained herein contradicts any disclosure with respect to a feature or integer disclosed in the previous applications, it will be understood that, to the extent of the contradiction, the present application will be taken as being correct for the purpose of the inventions and embodiments disclosed and defined in the present application.

The following references serve as a summary of the information referred to within the embodiment detailed by FIGS. 2a-2g

### Information and Set-Up for Embodiments Described Herein

Restaurant Set-up Rules (278): There are three basic embodiments disclosed herein, each of which utilise a different set of rules to set up a restaurant or any other space that can be reserved for any purpose. In all embodiments, the rules and constraints are arranged to permit the proper contextual relationships, relativities, utility of and flexible table and chair or equipment capacity to allow for effective differentiation, discrimination, yield management, dynamic pricing, revenue management, cost and operations management and the achievement of bespoke (configurable) individual quantitative and qualitative goals of a restaurant.

In the context of the specification and the embodiments and broader invention described herein, the terms “relationship”, “relativity”, “utility” and “contextual relationships” have specific meanings as related to equipment, furniture and other items which can be arranged within a space/venue and which can be ascribed specific attributes, constraints and by extension rules which utilise the attributes and constraints.

Firstly, the term “relativity” in the context of the specification refers to quantifiable attributes and constraints that describe quantifiable variables of a table, chair, furniture or equipment that in turn form the basis for a qualitative assessment of the table, chair and/or equipment. For example, the size and shape of the table, which are quantitative variables, may have an impact on a qualitative attribute of the table, such as the “class” of table. A first class table may be of a larger size and a first class chair may be more luxurious (larger chair). The attribute, however, is relative to other attributes and therefore in and of itself may not be determinative of the overall qualitative assessment of the table. For example, in addition to a physical attribute of the table, the location of the table relative to the space may also be determinative of the class of the table. For example, a table that is near a window and has a view may be considered a first class table, even if the physical attributes of the physical table do not necessarily match those of a “first class” table.

In other words, the term “relativity” refers to quantifiable attributes of furniture/equipment.

Correspondingly, the term “utility” refers to the overall utility that is derivable from the relative attributes and constraints that are associated with each item of furniture, including tables, chairs and other items of equipment.

Secondly, the term “relationship” refers to an association between two or more items, objects etc. For example, a relationship may be that a table is capable of being placed in a particular section. This is a constraint that defines a relationship between the table and the section.

Relationships may be one-to-one, or may be multiple, in that an object or item may have a relationship with a number of other objects or items. In other words, the relationships behave as a constraint with respect to how the two objects or items can interact.

In the past specification, the reference to a “contextual relationship” or to “context”, refers to a relationship that acts as a constraint when specific conditions are met. For example, two tables may have a contextual relationship when placed adjacent to each other, or together, but have no such relationship when they are not placed adjacent to each other.

The rules and constraints stand in contrast to the prior art solutions, which are limited to a predetermined and unchanging limited solution set of non-descript tables and table combinations with simple minimum and maximum chair constraints. The three embodiments shown at (278) are “space”, “tables” and “tables, table combinations and shadow tables” described further below:

### Space

The space embodiment uses a volumetric framework, and a restaurant floor plan or other file or data base to provide a series of restaurant allocation and organisation rules, including the relationships, relativities, utility and capacity of tables, chairs, other furniture and all other constraints within the restaurant.

### Tables

Each table is ascribed an extensive set of characteristics and constraints, such that each table has a specific relativity, relationship, utility and capacity relative to each other table. Moreover, each chair is also ascribed a space relativity which is treated as a second aspect of the invention. This embodiment is similar to the space embodiment noted above. However, there is no utilisation of exact dimensions. In other words, less emphasis is placed on the spatial/dimensional aspect of the “space”, but the rules and algorithm still mimic the “space” embodiment above to achieve a similar outcome. This additional embodiment permits the addition and/or removal of tables from the total capacity of the restaurant.

The use of a list of tables and associated attributes as the underlying set of variables used to define the relativity, relationship, utility and capacity of each table and chair acts as a “common denominator” or as a benchmark for those relativities, relationships, utilities and capacities that provides that relativity. Hence, the use of a list of tables detailing the relationships, relativities, utilities and capacity between each other is an embodiment of the claimed invention. A further embodiment is any combination or permutation of relativities, relationships utilities and capacities of tables, chairs, and the restaurant rules that permits the differentiation, discrimination, yield management, dynamic pricing, revenue management, cost and operations management to achieve bespoke outcomes as disclosed within this and the other related applications.

### Tables, Table Combinations and Shadow Tables

Through an extensive definition of the relationship, relativity, utility and capacity of each table and table combination with each other table and table combination to define a set of constraints rules can be applied to achieve desired outcomes. The development of rules provide granular differentiation and improve outcomes.

Within this embodiment is the concept of “shadow tables”, defined as tables that do not physically exist in the total solution set of tables and table combinations as in the prior art. Alternatively stated, these “shadow tables” are not shown and do not exist on the floor plan within the prior art. These “shadow tables” are a list of permutations of tables that can be placed in an area, sub area, or space such that they can replace previously existing table or table combination within that area, sub area or space such that the allocation process permits the addition of or removal of tables and or chairs from the floor plan to provide a different and more optimised outcome than the prior art.

It will be understood that the permutations are not limited to a fixed number of tables, but can include the addition or removal of tables. For example, a permutation may include two separate tables T1 and T2 and a combined table T1+T2 as per the prior art. However, in the present embodiment, there can also be provided a further table not existing in the prior art (T3) which permits the addition of a different combined table T1+T2+T3. In other words, the permutation allows for the incorporation of additional tables or removal of tables providing completely different configurations and numbers of table to vary the seating capacity, orientation, or any other aspect of the table combination in the sub area or area.

Embodiments and aspects of this application are supported by, and with further details provided within the additional related patent applications, but more specifically with the following related patent applications:

1. Space—as described in Table 1
2. Widget—as described in Table 1
3. Menus—as described in Table 1
4. Yield Management—as described in Table 1
5. POS Transactions—as described in Table 1
6. Rosters—as described in Table 1
7. Operations—as described in Table 1
8. Ordering and Allocation Integration—as described in Table 1
9. Gaming—as described in Table 1
10. Exchange—as described in Table 1
11. Artificial Intelligence—as described in Table 1
12. PCT Applications—as described in Table 1

The restaurant set-up rules shown at (278) in one embodiment also include set-up rules for all other spaces or purposes such as for the set-up and booking of functions and/or events with an area, subarea, private room or the entire restaurant. In a further embodiment the set-up rules referred to at (278) also refer to function spaces, event spaces, theatre, show and other spaces, such that a complete event can be enquired, modified, confirmed with or without part or full payment on-line and without the requirement of manual intervention by venue staff.

Embodiments are further described in related co-pending patent applications, with particular reference to the following related patent applications:

13. Functions—as described in Table 1

In a further embodiment, the restaurant set-up measurements provide information that permits a venue to detail the normal or standard set-up for a restaurant including the type, size and normal number of chairs that would be used for a table at a particular location. The restaurant set-up information can be used to determine if more than the standard number of chairs normally set for that table at that location is the physical maximum number of chairs that can be allocated to the table. In a further embodiment the restaurant set-up information can include information which indicates where one or more extra chairs can be placed on a table to increase the capacity of a table (which may also be determined by the relative location of the table in the venue).

For example where a table of two is placed up against a wall (and, hence the wall side is unusable) but, the other side can take an extra chair (as that chair will not be in a walk-way or interfere with any other table, the system is aware of the constraint and can add an extra chair to the table to increase its capacity if required during the booking allocation process.

In a further embodiment the information where the “change” of a table top from say one that is say 750 mm by 700 mm to one that is 800 mm round to permit the seating of 4 people and not 2 (as per the original 750 mm by 700 mm) in the same location, the restaurant set-up rules can include information as to when a restaurant reaches a certain threshold or capacity, such that the rules and algorithms can be used to apply one or more of increasing the capacity to some or all the tables to the maximum number of chairs; or to the maximum table top size, or some other permutation within the information provided and available within the restaurant set-up rules.

In another embodiment the restaurant set-up rules can be combined with any other information or any other permutation of the available information as described herein such that the restaurant allocation rules and algorithms can achieve any of the required quantitative and qualitative outcomes desired by the restaurant. For example, knowledge of the restaurant space, tables, table classes, table locations can be used in conjunction with the information available within a customer's history or CRM to allocate the customer's booking request instantaneously to their favourite or preferred table and preferred chair, or if the customer's favourite is not available to the customer's second preferred table and a preferred seating position, or failing that allocate the booking request to the next highest ranking class of table or table location as so on until that booking is allocated.

In one embodiment, the allocation of a booking can be associated with one physical space, physical item and the same booking can be transferred to another physical space or physical item such that a booking can comprise more than one “experience”. For example, a booking can be allocated to a bar table or bar stool for say 7 pm to 7:30 pm and then moved to the main dining room from 7:30 μm to 9:30 pm and then back to the bar at 9:30 pm for a night cap. In a further embodiment, as this sequence of events can treated as a single booking during the booking allocation process then the system can maintain all financial details and information within that one booking and one account so that information does not have to be manually transferred, or manually reconciled, including any pre-payments within the system or the process by which it is integrated within any POS system.

In a further embodiment the restaurant set-up rules referred to above could be applied to other industries and businesses including, for example, hairdressers, gyms, libraries, accommodation, car rentals and aviation, or any business that requires the allocation of a physical space, physical item during a booking allocation process.

In a further embodiment, the framework, rules, methods, procedures and algorithms, of the current invention can also be applied to the booking of appointments where the primary purpose of the appointment is not the physical space or a physical item but the provision of services such as legal advice, accounting advice, doctors' appointments, hospital appointments etc.

Menus (280): Menus and the use of menus, rather than simply being a presentation of products available for purchase, are integrated into various aspects of the broader system These include channel and widget configuration to offer different menus, not only by time, but by other constraints such as class and specific table; availability and search by different courses and menus; the ability to require customers to commit to different menus and different courses at different times; the ability to recognise and identify different channels and customers to offer specific menus and tailored menus with different conditions such as duration times, prices, payment conditions etc.; eliminate the need for indicating allergy details on menus as alternate menu items would be displayed that did not include the “offending” allergic ingredients, similarly with dietary requirements; the use of alternate menu items not only makes the display to the customer more friendly and personal but permits proper stock decrementing and revenue/sales analysis; the requirement for a customer to select a menu and the number of courses so that more accurate duration times can be calculated or requiring customers to accept variable duration times based on the number of courses they have selected in conjunction with one or more other constraints (such as occasion, time of booking, group size, etc.) in determining the duration a booking would be permitted to occupy a table; the integration of menus into a “product tree” to permit the seamless integration of pre-orders into point of sales systems and the seamless integration of the reconciliation process of prepayments and deposits without the need to create separate pre-paid accounts within POS systems. These embodiments shown at (280).

### Channel Configurability, Differentiation and Identification

In one embodiment, the claimed invention includes the ability of the operator to offer different menus with different dishes, different prices, different numbers of courses, different time durations and can be incorporated with different time durations and that specific information can be used and applied as part of the optimisation and booking allocation process.

### Individual Identification

In one embodiment, the booking allocation system can identify the customer seeking to make a booking and present them with an individual menu or another specific menu and with the knowledge of the individual access that individuals CRM details and apply other additional constraints with respect to their menu selection such as a different duration time or a different duration time at their preferred table as part of the optimisation and booking process.

### Required Selection of a Menus and or Courses

In one embodiment, a customer can be required to select a specific menu and or courses and with that required selection would be a set time such that the selection of the menu item and/o courses, a specific time duration could be applied to that selected menu and courses, incorporating other additional constraint information such as group size, occasion, day of the week, time of booking etc, to apply and or determine a duration time to be applied to that booking request and for that duration time to be used and applied as part of the booking allocation process.

### Alternate Menu Items

In one embodiment, a customer who has an allergy or dietary preference is only shown dishes that are compatible with their requirements, such that the menu item displayed does not include the inappropriate ingredients and simply shows the menu item as the dish will be presented when cooked.

### Menu Systems Integration

In one embodiment the booking allocation system contains a menu building module and/or a separate menu building module includes a product tree structure for the development of menu items (products) that contain ingredients for stock decrementing as well as alternate menu items and ingredients where those menu items are modified for allergies or dietary requirements so that proper stock decrementation can occur. In one embodiment, each menu item by being linked to a product tree permits seamless integration with POS systems, kitchen and bar printing.

In a further embodiment pre-orders are linked to the booking and there is no need to manually re-enter any pre-payments or pre-orders to a POS system as prepayment accounts as prepaid amounts can remain and be controlled within the ordering system and the booking allocation process such that an automatic reconciliation process can be applied when the booking arrives such that the manual transfer between accounts is not required.

Embodiments and aspects of this application are supported by, and with further details provided within the additional related patent application, but more specifically with the following related patent applications which are incorporated herein by reference:

14. Menus—as described in Table 1
15. Widget—as described in Table 1
16. Yield management—as described in Table 1
17. POS Transactions—as described in Table 1
18. Rosters—as described in Table 1
19. Functions—as described in Table 1
20. Artificial Intelligence—as described in Table 1
21. PCT Applications—as described in Table 1

Dynamic Pricing and Dynamic Product and Service Promotional Offers (282): The embodiments described herein include the complete differentiation of the products, services and benefits that can be utilised in the differentiation of a product and service during a booking or appointment process; the use of the complete list of options available for the differentiation of the product or service to create a unique set of differentiated products and services as compared to competitors that can then be offered to their customers; the use of the differentiated products and services as part of a booking or appointment process.

Through these processes, a restaurant online booking process, or other booking or appointment process can be used and permits a restaurant or other business to apply proper and complete yield management including dynamic pricing, peak period pricing, higher pricing of tables with better or higher utility, etc., as compared to the current practice of only offering simple discounts during off-peak periods and incorrectly referring to this as yield management. In a further embodiment the use of and the ability of adding the tailoring of a dining or other bookable experience or appointment such that additional, related or the simple re-arrangement of the sequence of activities can offer greater satisfaction and personalisation to create a total revenue management process. These embodiments are shown at (282) and include the differentiation of products.

In one embodiment additional constraints have been developed and incorporated within the booking allocation system including through the use of the volumetric framework within one embodiment of the invention to permit a full and complete differentiation of the products and services offered by a restaurant including differentiation not considered or accounted for by the prior art including by location, by ambiance, by class, by privacy, by individual table, by ranking of each individual table, by menu, by number of courses, by occasion, by category of customer, by ranking of customer, by event, by conditions or constraints by time of booking, by payment terms, by additional supplementary items committed to, by channel and then these additional differentiation aspects being incorporated and used within the booking allocation process so that the a restaurant can configure these items to optimise their preferred quantitative and qualitative outcomes.

### The Yield Management and Revenue Management of Products

In one embodiment the additional product differentiation referred to above is utilised by the claimed invention to permit the control of capacity offered by differentiated products and services and then to apply yield management techniques which permit the incorporation of dynamic pricing, differential pricing by the differentiated items. In a further embodiment the incorporation of additional and supplementary items including the ability to tailor the sequence of events within a booking or appointment (as one simple example of this embodiment is the ability to permit customers to design their own sharing platters and eliminating the need have an entrée and/or a main course in a traditionally three course a la carte restaurant.

### Promotions

In one embodiment the incorporation of configurable promotions, configurable back fill promotions, and interactive tactical upsell promotions to people hesitating during the booking process or to people who have already booked or to encouraging people to pre-order or while at the restaurant in-service ordering process.

### Sale of Specific Tables and Packages, Auction of Specific Tables and Packages and the Sale of Specific Tables or Packages Through a Restaurant Table Exchange.

In one embodiment the incorporation the sale of specific tables or packages by individual sale by the restaurant or through an “exchange”, “website” or other process that permits the resale of the tables and packages.

### Butler and Concierge Service

In one embodiment there is provided a module that allows the incorporation of additional third-party or ancillary items to personalise the restaurant experience, change the order of service, provide bespoke offerings and experiences not normally or traditionally provided by restaurants, upsell during the booking and ordering process unusual items so that a restaurant can create greater differentiation to competitors. These experiences are not limited to the experiences normally provided by restaurants but targeted at experiences and offering that are outside existing norms to include anything desired by a customer and within the level of acceptability of the restaurant. In a further embodiment the additional information, spending and revenue for a booking can be used within the booking allocation process to provide higher spending, higher revenue, higher contribution or other classification of customers, or more specific experience requirements in the booking allocation process of the claimed invention. In one embodiment this can result in a higher spending customer being given a better table or being provided with an upgrade to a better class of table, extended duration or other benefits or preferential treatment.

Embodiments and aspects of this application are supported by, and with further details provided within the additional related patent applications, but more specifically with the following related patent applications which are incorporated herein by reference:

22. Widget—as described in Table 1
23. Yield management—as described in Table 1
24. Space—as described in Table 1
25. Exchange—as described in Table 1
26. Gaming—as described in Table 1
27. Rosters—as described in Table 1
28. POS Transactions—as described in Table 1
29. Artificial Intelligence—as described in Table 1

Special Events Scheduled by Venue (284): In some embodiments, there is provided a process by which special events may be included by utilising the forecasting and planning modules to create and classify specific events as “one off” events so that they can be properly understood and interpreted by the forecasting modules and therefore also correctly classified and utilised as input data by the artificial intelligence module. More specifically these embodiments are shown at (284).

Embodiments and aspects of this application are supported by, and with further details provided within the additional related patent applications, but more specifically with the following related patent applications which are incorporated herein by reference:

30. Yield Management—as described in Table 1
31. Rosters—as described in Table 1
32. Artificial Intelligence—as described in Table 1

CRM (286): In the embodiments described herein, the CRM is not merely a repository of information and historical data base, as is the case with all prior art, but is a system that contains constraints and information that can be accessed and utilised as part of the booking allocation process. These embodiments include the allocation of a Super VIP and or VIP to their favourite or preferred table automatically during the booking allocation process and not through a manual allocation process undertaken after the booking is accepted, as is the case with the prior art.

Further, in additional embodiments the restaurant or the venue can provide additional information and constraints as to how this CRM information should be utilised, how it should be enhanced, modified or applied during the booking allocation process, including, the addition of complementary items being added to their “running sheet” or “order of service” for their booking, for example, a free glass of wine, or an extended booking duration time, that no deposit or prepayment is required unlike other bookings or other benefit or information.

In a further embodiment, the booking allocation process can automatically embellish the booking allocation process by permitting differentiation between customers and better tailoring and personalise a person's restaurant experience. More specifically these embodiments are shown at (286). Embodiments and aspects of this application are supported by, and with further details provided within all the additional related patent applications:

External Websites (288): In some embodiments, external websites are utilised as not merely a source of information or reference data but as data and information that can be accessed and utilised in the booking allocation process. Embodiments of the allocation methodology, processes and rules can include, a person's social media influence rating, a person's occupation, or other distinguishing feature as inputs to determine the constraints to be utilised by the booking allocation process. More specifically these embodiments are shown at (288)

Embodiments and aspects of this application are supported by, and with further details provided within the additional related patent applications.

Forecasting and Predictive Model (290): The level of detail used by the embodiments in the differentiation of the product or service, yield management, dynamic pricing, revenue management, the detail within a restaurant the personalisation of services etc., allow the forecasting and predictive model of the embodiment to be extremely sensitive and therefore results in far more accurate forecasts and predictions as there is greater monitoring ability as well as “levers” to make changes to achieve desired outcomes.

Specifically in one embodiment the forecasting and predictive model directly accesses the extensive constraints, variables, inputs, historical outcomes and trends, allocation rules, as well as planned events, third party websites, and use that information to develop its forecasts and then to monitor activity against those forecasts by the allocation methods, procedures, algorithms and allocation rules in the allocation of bookings to a space, a table, a table combination, chair or other item to achieve better forecasts and to make changes to the constraints so as to achieve even better outcomes. Embodiments also include the forecasts of functions and events as well as the monitoring of those events and the recommendation of changes or the making of changes to the applied constraints; booking capacities; booking classes; staffing; rosters; resource requirements; operational requirements; maintenance requirements, etc. More specifically these embodiments are shown at (290). Embodiments and aspects of this application are supported by, and with further details provided within the additional related patent applications, but more specifically with the following patent applications:

33. Yield management—as described in Table 1
34. Rosters—as described in Table 1
35. Artificial Intelligence—as described in Table 1
36. Functions—as described in Table 1
37. Operations—as described in Table 1
38. PCT applications—as described in Table 1

Suppliers (292): Orders; Deliveries; Constraints, details etc. (292) The embodiment includes the ability to link a supplier to the booking allocation process such that the suppliers items can be offered within the booking process, the selection of what a person has chosen can then be added to the booking allocation process and algorithm and then an order be placed with the supplier when a person confirms their booking to create a completely integrated process. Embodiments of this process are supported by, and with further details provided within the additional related patent applications.

Database of Booking Requests (294): In one embodiment, the historical booking requests are directly accessed by the booking allocation methods, procedures, algorithms and allocation rules for the allocation of bookings to a space, a table, a table combination, chair, other item or for the allocation or creation of an appointment.

In a further embodiment additional information can be added to the data base of historical booking requests, their behaviour at the restaurant, the allocation provided to them in previous booking requests, overall demand for a time or a service that could not be satisfied and the timing and booking profile of those bookings, etc., (294) Embodiments and aspects of this application are supported by, and with further details provided within the additional related patent applications.

Optimisation Quantitative and Qualitative Strategic Rules and Outcomes (296): Embodiments of the allocations, methods, procedures, algorithms and allocation rules include the creation of specific rules to undertake specific outcomes which can be selected by a venue to create specific outcomes dynamically (the prior art cannot dynamically allocate bookings and relies on a predetermined single priority table and table combination list to allocate bookings).

The specific dynamic allocation can also be combined in different sequences combinations by different time periods, different services, etc., so as to create bespoke outcomes for the benefit of individual venues to better meet their targeted goals and the requirements of their customers. Embodiments with respect to this aspect are not limited to the following examples, detailed; Floor Space Optimisation Algorithm; Time Related Optimisation Algorithm; Event Related Optimisation Algorithm; Strategy Related Optimisation Algorithm; Third-Party Optimisation Algorithm; Pre-service Optimisation Algorithm; In-service Optimisation Algorithm; Self-Seating Optimisation Algorithm (296). Embodiments and aspects of this application are supported by, and with further details provided within all the additional patent applications:

39. PCT applications—as described in Table 1

Resource Parameters (298): The resource parameters include; Venue set-up times, bar set-up times, hosting requirements, kitchen set-up times, roster structures and frameworks including staff metrics such as customers that each staff member can cater for, minimum staffing levels, amount of food that each chef or food station can produce, minimum hours, pay rates, broken chairs, broken tables, equipment out of service etc. (298). Embodiments and aspects of this application are supported by, and with further details provided within the additional related patent applications, but more specifically with the following patent applications:

40. Rosters—as described in Table 1
41. Operations—as described in Table 1
42. Artificial Intelligence—as described in Table 1

Reporting (231): Performance analysis; Customer satisfaction; Deliverables; Labour Analysis; Actual v. Predicted etc. (231) Reporting relates to the additional constraints possible within the claimed invention and the analysis of those constraints and their outcomes. In one embodiment, reporting relates to the use of that analysis to better forecast and utilise that information to create a feedback loop and information to the artificial intelligence module so that it can continually learn and improve this processes and outcomes. This application is supported by, and with further details provided within the additional related patent applications, but more specifically with the following patent applications:

43. Yield Management—as described in Table 1
44. Artificial Intelligence—as described in Table 1

Database Historical Information (233): Database historical information relate to information not currently available or used by the prior art. This information includes: booking duration times by courses, by individual table, by class of table, by occasion etc.; the time bookings made—booking time; classes of bookings; spend by booking types; yield management outcomes; revenue efficiency; walk-in promotions; etc. and wherein this information can be accessed and utilised within the booking allocation process and all other modules including forecasting and artificial intelligence (233) this application is supported by, and with further details provided within the additional related patent applications, but more specifically with the following patent applications, but more specifically with the following patent applications:

45. Yield—as described in Table 1
46. Artificial Intelligence—as described in Table 1

External Websites (235): External websites including weather information relate to information that is accessed and used by the current invention within it booking allocation process, forecasting and artificial intelligence. Embodiments relating to the use of information from external websites within the claimed are supported by, and with further details provided within the additional related patent applications.

Printed Operational In-Service Run Sheets (237): Printed operational and in-service run sheets relate to information that includes the results of the autonomous booking allocation process, the autonomous chair allocation or selection process etc., and is supported by, and with further details provided within the additional related patent applications.

Operational Requirements and Planning (239): Operational requirements and planning within this application refer to staffing levels; rosters, including roster frameworks and standard rosters, roster creation, staff allocation to rosters, adjustments to rosters based on bookings received as compared to bookings forecasted; start/finish times, including pre-times, set-up times, closing procedures and times; orders; delivery schedules; maintenance planning; equipment replacement; occupational health and safety; procedure and policy monitoring; etc. (239). Embodiments within this aspect of the application are supported by, and with further details provided within the additional related patent applications, but more specifically:

47. Rostering—as described in Table 1
48. Operations—as described in Table 1
49. POS Transactions—as described in Table 1

Point of Sale Integration (241): In one aspect, embodiments of the point of sale (POS) integration relate to transactional aspects. These embodiments include the “real time” dynamic floor plan created by the claimed invention being integrated into POS systems with or without the application of the Cartesian “volumetric framework” (which in one embodiment includes more than a three dimensional volumetric framework, as it can include more than three axis) within the integrated POS systems such that the “real time dynamic floor plan” including details of the table, the chairs and booking details by chair, replaces the existing static floor plan within the prior art POS systems. The benefits of this dynamic real time floor plan ensure that restaurant tables are always shown as how they appear in real life, that the tables have the correct table numbers, that the tables show the correct chair set up and all pre-orders are shown on the correct table and the correct chair numbers that change in accordance with the customers request and the booking allocation process.

In a further embodiment any pre-payments, part payments or deposits including food, beverage and other items are transferred and referenced in detail by the booking system or ordering system, to the POS system on arrival and eliminate the need for the opening of pre-paid accounts within POS systems or other accounting systems which then require manual transfer of amounts between accounts etc. and a subsequent manual reconciliation process. Embodiments, therefore include integrations for dynamic floor plans; table and chair seating plans, allocations and details; orders; payments; deposits; sale items; Etc.; CRM detail integration as it related to the booking allocation and ordering processes of the current invention (241) Embodiments of this application are supported by, and with further details provided within the additional related patent applications:

50. POS Transactions—as described in Table 1
51. Space—as described in Table 1
52. Menus—as described in Table 1

In a further embodiment, the booking allocation system incorporates a transaction system that replaces and enhances the functionality of a traditional P.O.S. system. A transaction system is far more efficient and renders a traditional P.O.S. system obsolete, as most transactions do not occur at one point (hence the current name and terminology of Point-of-Sale systems) but the transactions occur at multiple points and the traditional P.O.S. systems no longer represent an efficient core revenue or accounting system.

In a further aspect the current invention with respect to POS systems relates to the integration and use of POS systems with a booking allocation system such that a person making an order at a counter can be allocated a table and or seat within the venue at the same time with or without a stipulated duration time. In another embodiment a person making an order at an ordering kiosk within a venue can be allocated a table or a seat at the venue with or without a stipulated duration time. In another embodiment where a person is allowed to enter a venue and choose a table or seat of their choice and then order, the embodiment through the integration of a booking system can advise the person how long they can occupy or use the table or chair. In another embodiment through the integration of a seating kiosk (self-seating kiosk), an appointment app a person can be allocated a table including duration permitted. In other embodiments the application of the invention to gyms, hairdressers and even to the appointment setting processes of lawyers etc. Embodiments of this application are supported by, and with further details provided within the additional related patent applications and more specifically:

53. Ordering and Allocation Integration—as described in Table 1

Stock Control, Ordering and Purchasing (243) In one aspect, embodiments of stock control relate the creation of alternate menu item for allergies and dietary requirements of the claimed invention. In one aspect the ordering and purchasing of the claimed invention relate to the creation offering for sale items not traditionally associated with restaurants and the automation of the transactional aspects so that no manual intervention or work is required. This includes the ordering of additional tables and chairs if the allocation model determines the requirement for additional furniture. Embodiments and aspects of this application are supported by, and with further details provided within the additional related patent applications:

1. Space—as described in Table 1
2. Rosters—as described in Table 1
3. POS Transactions—as described in Table 1

Home Delivery and Takeaway Integrations for Production and Time Scheduling (245) In one aspect, embodiments of the home delivery, takeaway integrations for production and time scheduling include the monitoring of time durations, and the autonomous turning on, turning off, or provision of time information concerning food production times, yield management, dynamic pricing and point of sale (POS) integration of the transactional aspects. Embodiments and aspects of this application are supported by, and with further details provided within all the relevant patent applications.

Payment Rules (247): In one aspect, embodiments of payments include the ability to have different payment rules for different menus, different courses, different booking times, different prices by booking channel, etc., so that a completely dynamic pricing system and payment constraints are created. Embodiments include; payment decision trees; prepayment and payment constraints, different channel constraints, product differentiation, dynamic pricing etc. (247) Embodiments and aspects of this application are supported by, and with further details provided within the additional related patent applications.

Artificial Intelligence (251): In one aspect, embodiments of artificial intelligence include the complete automation of the entire restaurant process from a systems perspective which is beyond the ability and scope of prior art systems. Including data mining, advanced analytics, modelling and predictive analysis to automatically amend constraints. (251) Embodiments and aspects of this application are supported by, and with further details provided within additional patent applications and more specifically by the following applications:

2. Artificial Intelligence—as described in Table 1
3. Yield Management—as described in Table 1

Alternate Payment Systems (253): In one aspect, embodiments of the alternate payment systems is the ability of a venue to offer alternate payment such as a progress payment option, not available within the prior art. This becomes a viable option within the claimed invention as the autonomous reconciliation of part payments means that the manual reconciliation processes and labour burdens of the prior art are no longer cost prohibitive. Embodiments and aspects of this application are supported by, and with further details provided within the additional related patent applications.

Referring to FIGS. 2a to 2e, the following references are provided as a summary of one embodiment of the information referred to within the flow chart as “Claimed Invention” 276, “Intuitive booking allocation super highway” (297) and booking allocation information 2026, utilising the information and constraints identified and developed 1a to 1v above:

Processes, Methods and Algorithms within the Current Invention

User, in one embodiment (255)

Various Configurable Access Channels, such that the offers, products services etc., can be completely different by channel (257)

Configurable User/User Interfaces: Restaurant booking widget, function booking widget, self-seating kiosk, self-seating app, restaurant booking app, menu pre-ordering app/widget, promotional apps/widgets, booking form, and integrated systems such as POS systems. (259)

User requirements used in the Booking Allocation: Buy a specific table, request a specific table, request an extended dining duration, flowers, chocolates, card, entertainment, gift, different order of service, personal waiter, specific personal waiter, budget, occasion etc. (261)

Strategic Control of Capacity, Product and Services for Booking Allocations: Strategic capacity availability by Area, Sub-area, Section and Class. Strategic Product and Service Availability by Menu, by Courses, by Variable Time Durations to meet revenue and yield management targets. (263)

Booking Allocation for the Optimisation of Space: (Sale of specific tables with guaranteed allocation, Super VIP guaranteed seating, VIP prioritised seating, Optimisation of remaining table allocations to Area, Sub-areas, Sections and Classes based on venue strategy, the introduction of additional tables and/or chairs, the removal of tables and/or chairs, the interchange of tables, the interchange of table tops, etc. (265)

Payment/Deposit Confirmation (267)

Butler Service: Ordering of 3^{rd} Party Services/Products, the changing of the order of service, the introduction of items not traditionally offered by restaurants. (271)

Time-Related Booking Optimisation: At a predetermined time (e.g. 1 hr before service), reallocation of all bookings to offer the best tables to the highest ranking, non-guaranteed table-allocated customers (Musical Chairs) (269)

Event-Related Booking Optimisation: At the occurrence of an event, e.g.: Rain, reallocation of outdoor bookings to tables in undercover Areas, Sub-areas, Sections and Classes. Such a reallocation can be automatic through a linking of the booking process to a third party weather site or through a re-allocation allocation process that has been programmed and can identify the weather affected tables. (273)

Capacity-Related Booking Optimisation: An event that a particular class of table is at full capacity, a determination if demand for other classes of tables is such that they can be reduced and additional tables offered for the class in demand. (275)

Strategy-Related Booking Optimisation: An ambience re-allocation: if restaurant is not expected to fill up or other parameters apply. (277)

Third Party Information Booking Optimisation: Theatre information, website information which may have an impact on capacity decision. E.g. allocating bookings to a minimum space in anticipation of a full theatre next door. (279)

Pre-service Booking Allocation Optimisation: A final optimisation before service taking all the above factors into account, as well as opening up capacity for walk-ins, if such capacity had been previously excluded from the allocated capacity. Creation of run sheets and service notes for staff. If a venue selects self-seating option, floor plans and seating locations as they would appear at time of arrival of each booking are sent to each customer. (281)

Cockpit Dashboard: Dynamic Floor Plan; Time-based floor plan, the booking system having an inbuilt POS system, and the ability to take orders, receive orders, reconcile accounts, etc. including integration to other systems including other POS systems to create a completely integrated dynamic real-time systems environment (283)

In-service Booking Allocation Optimisation: Optimisation can be based on any combination or permutation of the above optimisation algorithms or different algorithms which can only use tables located within the restaurant and/or without moving pre-allocated bookings and/or allocating bookings based on space optimisation or other dimension such as allocation to the best table. (285)

Self-Seating Kiosk (Booking Allocation): Applicable for venues that have selected the self-seating option. The kiosk can provide information on the seating location of confirmed bookings as well as the ability of accepting new walk in bookings as well as providing direction such that a host or someone to seat guests is not required. (287)

Autonomous Restaurant and Complete Integration: Fully integrated information system including table and position sensors. (289)

Point of Sale System: A fully integrated with dynamic real-time table plan layout with orders sent to kitchen and bar as appropriate and automatic reconciliations. (291)

Payments: Fully integrated with links to original booking including part payments by table, customer and position number. (293)

Accounting System: The complete integration of the booking systems with all accounting and transaction systems to produce all reports including revenue; P&L statements such that manual input is minimal (295). Including the implementation of a volumetric framework within the various accounting systems, for example the use of the volumetric framework for per-ordering, the POS system and other accounting systems.

Referring to FIGS. 2f to 2g, the following references are provided as a summary of the information referred to within the flow chart as “Prior Art” 223, “Reactive Allocation” 2030 with booking allocation information 2032:

Prior Art (223)

User (2000)

Access Channels (2002)

User/User Interfaces: Restaurant Booking Widget, Booking Form. (2004)

User requirements used in the Booking Allocation: (Prior Art) Date, time, meal period, pax (2006)

Strategic Control of Capacity, Product and Services for Booking Allocations: (Prior Art) Capacity and Max Group Size by booking time interval for a standard time duration for the whole service or by group size (2008).

Payment/Deposit Confirmation (2010)

Allocation of Booking Request: (Prior Art) Use of a prioritised list of tables and table combinations to allocate bookings. Prior Art process finishes with this step. (2012)

Dashboard: Static Floor Plan (2014)

Payments (2016)

Referring to FIG. 2f and FIG. 2g, the following references are provided as a summary of the information referred to within the flow chart as “Prior Art” 223, “Booking Allocation Information” 2032:

Restaurant Set-up Rules: Open/closed; Meal periods; Floor Plan (not to scale); Seat block-outs; Rooms, Areas, Bars; Tables and table combinations prioritised list; Standard booking time duration or by group size (2020)

Promotional Offers: Discount by time interval (2022)

Database: List of unused tables and table combinations (2024)

It will be understood that the description with regard to FIG. 2a to FIG. 2e are not to be taken as an exhaustive description of the invention or embodiments, but rather a summary of an embodiment, to enable a person skilled in the art to gain an understanding of the broader inventive concept. It will be understood that the preceding and subsequent Figures describe the specific embodiments and aspects as are claimed herein in more detail and provide examples of reduction to practice. Moreover, the description with regard to FIG. 2a to FIG. 2e are not to be taken as evidence that the inventive concept is “abstract” or the mere implementation of an abstract concept. Rather, the description of FIG. 2a to FIG. 2e is intended as a primer or high-level view of the system as a whole, to enable the person skilled in the art to better understand the inventive concept.

It will be understood that the description with regard to FIGS. 2a to 2e are not prescriptive in that all herein features, steps and algorithms are required to be taken or taken in the order that they are shown the description or that they form a definitive list of features, steps and algorithms that comprise the invention. The purpose of FIGS. 2a to 2e and the comparison to a prior art system shown in FIGS. 2f and 2g is to highlight the inventive concept of using the knowledge of space, objects and their relativity and utility data combined with a series of algorithms optimise a space based on the strategic parameters or constraints of a venue.

Moreover, there is described below a series of algorithms, which for convenience, are numbered. However, it will be understood that each algorithm is independent, and the numbering is not reflective of any specific order in which the algorithms are to be applied. The embodiment may apply one or more algorithms dependent on constraint information and the application can be separate to other algorithms, in conjunction with one or more other algorithms, in different sequences with the one or more other algorithms to achieve the desired outcomes for the booking time period in question. The application, sequence, mixture of the algorithms can be configured by each individual restaurant in accordance with their individual strategies and required outcomes.

The first embodiment referred to as the First Algorithm is termed the “Strategic Capacity Control” algorithm, module 263, which makes an assessment of requests based on availability with reference to allocations by space, subspace, class, by time, allowing capacity for walk-ins, by menu, by course, etc.

The second embodiment referred to as the Second Algorithm is termed the “Optimisation of Space Outcomes” module 265, and is relevant to guaranteed table allocations. The algorithm which is an iterative seating optimisation algorithm which is arranged to allocate seating first to Super VIP's and guaranteed seating allocations then based on availability by VIP, group size, etc., to optimise the allocation and position of tables. This algorithm is arranged to optimise floor space efficiency around guaranteed table allocations.

The third embodiment referred to as the Third Algorithm is termed the “Time Related Optimisation” algorithm, module 269, which is best described by an example. For example, one hour before service, if it is decided that no new tables should be added, all bookings are reviewed, and, if there are two different bookings at 6 pm and one booking is from a regular customer and one is from a first time visitor, the regular customer is allocated to the better table and the first time customer is allocated to the other table.

The fourth embodiment referred to as the Fourth Algorithm is termed the “Event Related Optimisation” algorithm, module, 273, which is triggered or undertaken by the occurrence of an event. For example, if it rains, the algorithm would re-allocate part or all of the bookings to outside tables to inside tables as all or part of the outside tables may be rendered unusable.

The fifth embodiment referred to as the Fifth Algorithm is termed the “Full Capacity Optimisation”, module, 275, which is triggered or undertaken when one space, subspace, or class is full. For example, if a specific class within the restaurant was full the algorithm would evaluate if demand for the other classes for that service had availability. If other classes had availability then it would determine if those tables would be filled and what the revenue and contribution would be and if it then determined that it would be best to increase the size of the class that was full and reduce the seating availability in another class it could do so and increase the capacity within the class for which the booking request was received and allocate the booking request against one of the additional tables created in the expanded class.

The sixth embodiment referred to as the Sixth Algorithm is termed the “Strategy and Ambiance Optimisation”, module 277, algorithm. All bookings are reviewed, and if it is found that the restaurant will not be at capacity, the bookings are spread around the restaurant so that a better ambience is achieved within the restaurant. For example, if a restaurant only has two bookings for a Monday evening, the Second Algorithm may have sat both bookings next to each other in a back corner of the restaurant as this was the most efficient use of the restaurant space. This algorithm recognises that this arrangement is not an ideal seating arrangement for an empty restaurant and allocates the two bookings in this example to give both bookings the two best available tables.

The seventh embodiment referred to as the Seventh Algorithm is termed the “Third Party Information Optimisation”, module 279 algorithm. For example, the optimisation algorithm could access third party information such as the bookings for the local theatre and the start and finish times of a show to determine capacity allotments and constraints. Further, it can determine not to offer discounts or promotions at 9 pm as the theatre will finish and it expects numerous walk-in customers.

The eighth embodiment referred to as the Eighth Algorithm is termed the “Pre-Service Quantitative and Qualitative” algorithm, module 281. This is the final optimisation algorithm before a service and can be a combination of one or more of the previous algorithms at the discretion of the restaurant manager. It is run at a predetermined time before service and is also used to create run sheets and provide information to restaurant staff as well as provide final seating plans and arrangements for self-seating customers. As another example, as a restaurant can be split into different classes part of a restaurant can offer self-seating and part of a restaurant can offer full table service.

The ninth embodiment referred to as the Ninth Algorithm is termed the “In-service Allocations without additional tables or changing existing table allocations” algorithm, module 285. This algorithm is executed after service begins and new bookings are limited to the use of only tables physically available within the restaurant. The in-service optimisation process uses the In-service Allocations algorithm to provide a limited optimisation process which limits the allocation process by means of additional constraints to optimise request allocation process with minimise the disturbance to current patrons.

The Ninth Algorithm is not mandatory as the eighth algorithm or any other algorithm or a combination thereof could continue to be used without the need to unseat existing bookings whilst maintaining the ability to add or remove one or more tables. Further, additional algorithms or variations of the booking algorithms could be added to provide additional and different allocation outcomes and as a consequence provide additional tools for both the customer and the restaurant to achieve their preferred objectives and customer service standards.

A co-pending PCT application filed contemporaneously with this application in the name of Grand Performance Online Pty Ltd and entitled “A COMPUTER-ENABLED METHOD, SYSTEM AND COMPUTER PROGRAM FOR PROVIDING AN INTUITIVE USER INTERFACE ARRANGED TO CREATE A DYNAMIC FLOOR PLAN UTILISABLE BY AN ALLOCATION ALGORITHM TO PERFORM THE TASK OF ALLOCATING A SPACE, FURNITURE, EQUIPMENT OR SERVICE” includes a number of annexures number 1 to 11, which are herein incorporated by reference. Referring to Annexures 1 to 11 details are provided of the measures and metrics used by the prior art and by the embodiments and broader invention described herein which are significantly greater and beyond the scope, functionality, integration and ability of the prior art. Specifically the prior art measures and metrics are contained within Annexure 1 while embodiments of the measures and metrics utilised within our claimed invention are detailed in annexures 2 to 11. The prior art is extremely limited in the ability to analyse and report as the prior art firstly does not appreciate and recognise the importance of additional measures and metrics for reporting, forecasting and artificial intelligence. Secondly the prior art does not have the structures, methods and procedures to be capable of calculating the measures and metric calculations to achieve better outcomes. Two such measures are “revenue yield” and “efficiency”.

Referring to Annexures 1 to 11 the following references are provided as a summary of the measures and metrics detailed within the Annexures:

Annexure 1 Prior art measures and metrics: This annexure highlights the prior art metrics and measures are limited to a limited number of practical and theoretical measures that are used and taught within universities to measure restaurant performance and measurements.

Annexure 2 Floor plan guidelines, rankings, and space efficiency measures for the claimed invention: This annexure provides variables related to spatial guidelines and measures, such as; floor space allocation, dining, bar and customer spaces, table top guide, fixed and flexible seating areas including walkways, chair size guide, spacing between tables, waiter stations guide, bar space and bar stools guide, area per person size guide, area per person size guide, area, sub-area, class, section, and table and stool rankings, table analysis, tables for sale, tables for auction, tables dedicated to specific channels, location analysis and floor space efficiency.

Annexure 3 Capacity utilisation and revenue efficiency measures for the claimed invention: This annexure provides variables related to capacity, utilisation and revenue efficiency measures, which include the concept of dynamic floor plans which is a concept of the claimed invention where by additional tables and chairs can be added to a floor plan during the booking allocation process and these additional tables and chairs need to be included within these performance measures and metrics. These measures and metrics include; revenue yield, seat capacity (production) and utilisation, table capacity (production) and utilisation, units of measure of capacity, physical constraints, hours open, service periods open, service hours open, back of house (kitchen) hours, front of house (dining room) hours, revenue measures.

Annexure 4 Booking Analysis for the claimed invention: This annexure provides variables related to booking analysis, such as; Booking requests allocated analysis, booking profile analysis, booking requests rejected analysis, source of booking analysis.

Annexure 5 Duration Time Analysis for the claimed invention: This annexure provides variables related to duration time analysis, such as; duration times by booking size, by occasion, by menu selected, by courses selected, by booking time, by booking day, by customer type, by requests for extended durations, by duration times extended, by table, by class.

Annexure 6 Product Mix Analysis for the claimed invention: This annexure provides variables related to a product mix analysis, for areas, subareas, classes, sections, tables, distribution and channel for items such as; food: by time, by service, by day, by server, by channel; Beverage: by time, by service, by day, by server, by channel; Supplementary items: by time, by service, by day, by server, by channel.

Annexure 7 Revenue and Customer Performance Analysis for the claimed invention: This annexure provides variables related to revenue and customer performance analysis, such as; detailed revenue analysis, detailed customer analysis detailed customer ranking and detailed channel analysis.

Annexure 8 Staff and Roster Parameters for the claimed invention: This annexure provides variables related to staff ratios, requirements, hours, set-up times for the creation of forecasted rosters, performance measurements against those rosters and the use of artificial intelligence to update and maintain those performance measures and use the information to create further improvements to those rosters.

Annexure 9 Profit and Loss Layout (a la carte) structure and definitions for variable costs and fixed costs and contribution analysis for the claimed invention: This annexure variables related to the structure and the relationship between revenue and costs and how those revenues and costs can be determined and understood from a contribution perspective and marginal cost perspective such that decisions and actions taken can be measured in terms of cash generation, contribution and performance for reporting, forecasting as well as for feedback in the artificial intelligence loop.

Annexure 10 Break Even Analysis, Contribution Margins and Variable Pricing Analysis for the claimed invention: This annexure provides variables related to the specific analysis of the financial performance of the claimed invention, the monitoring of the financial performance, for forecasting and for the use of these measures and metrics for learning and artificial intelligence within the framework of the other annexures detailed within this embodiment. This analysis includes; break even analysis utilising the defined profit and loss statement within annexure 9 and other cost performance and analysis measures.

Annexure 11 Supplier Pricing Comparisons and Monitoring for the claimed invention: This annexure provides variables related to requesting comparative pricing, supplier performance and reliability and the monitoring of their performance for recommendations and the automatic placement of orders.

Those skilled in the art can appreciate that the structure of the claimed invention, and more specifically with the measures and metrics referred to within the annexures, that these measures and metrics can easily be converted or adopted within the other industries referred to and to which this claimed invention can be applied to.

### Volumetric Framework and Integration of Artificial Intelligence Engine

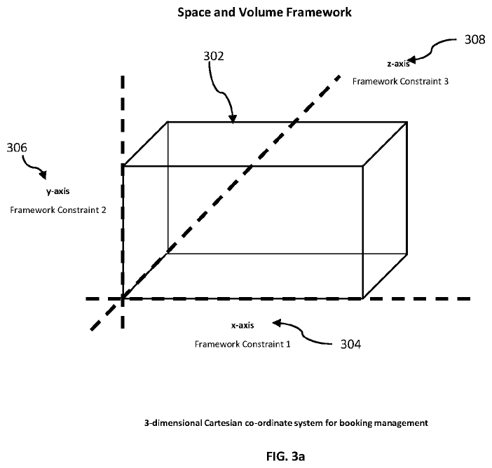

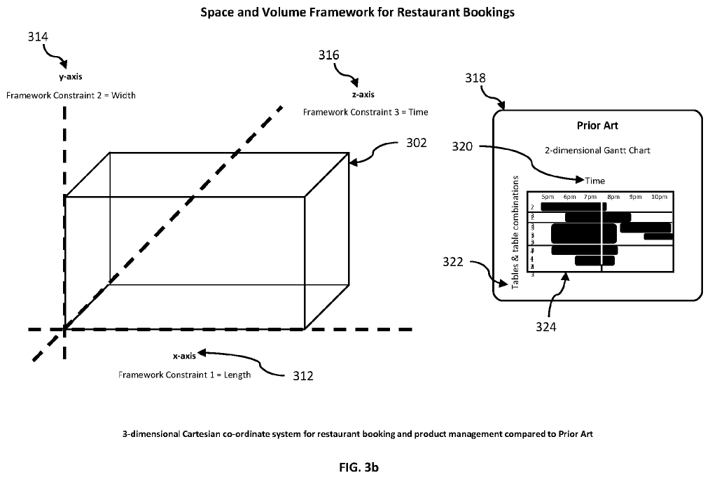

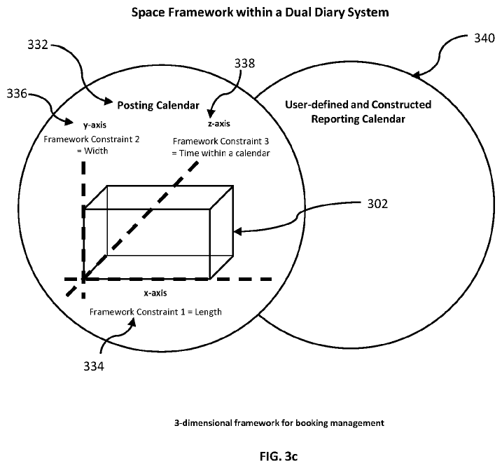

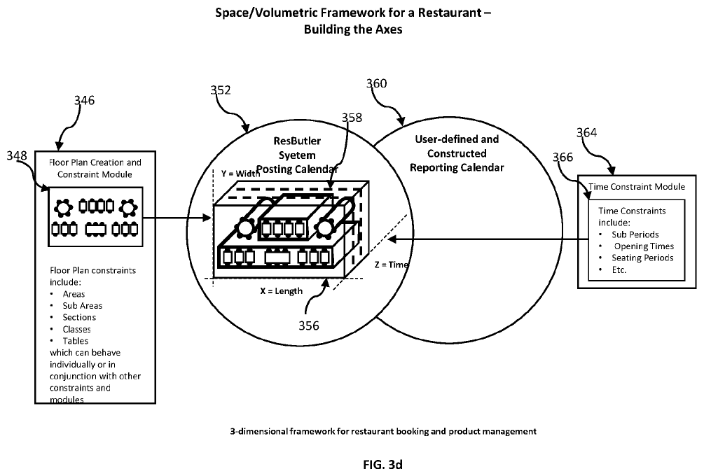

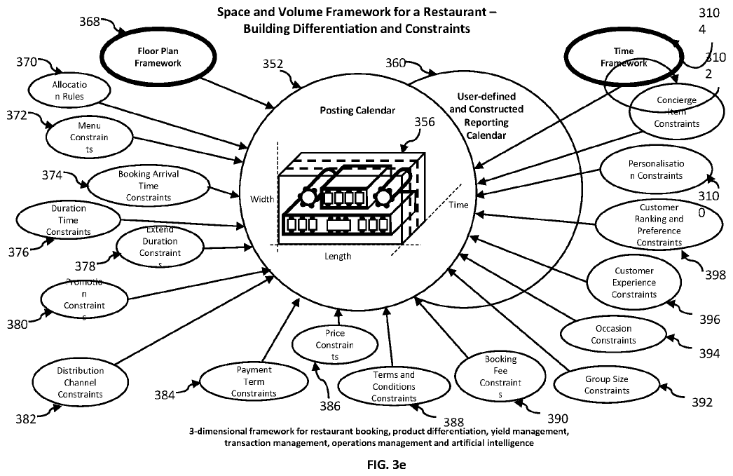

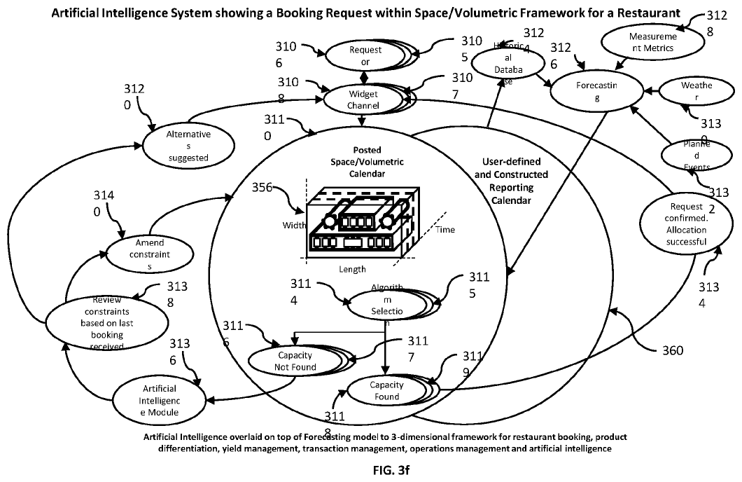

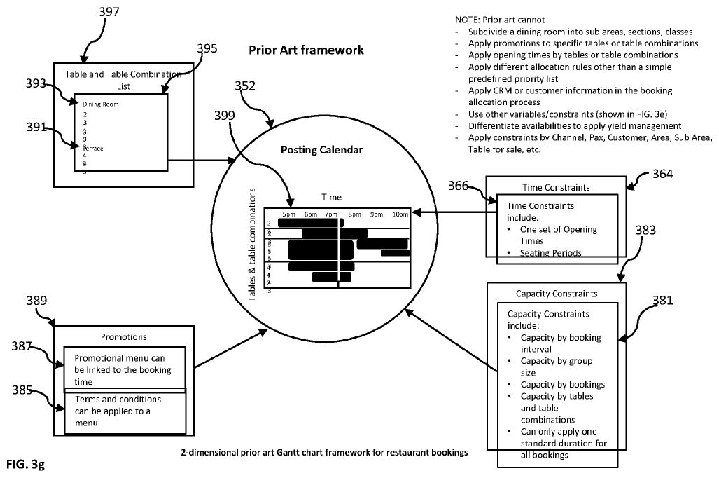

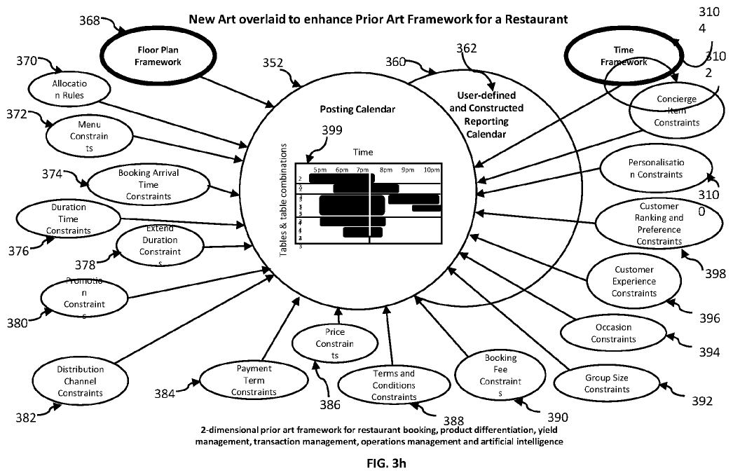

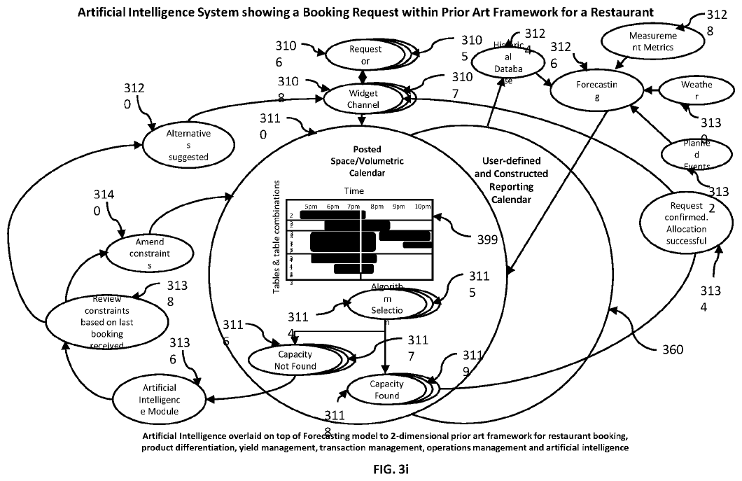

Referring to FIG. 3a, there is shown a diagrammatic representation of a space and volume framework 302. The framework 302 is based on a cartesian three-dimensional framework, which acts as a frame of reference to allow for the visualisation of the elements required to operate a space, including the physical movement of items within the space. The volumetric framework 302 operates across three axes, generically labelled the x-axis 304, the y-axis 306 and the z-axis 308. Each of the axes allow a constraint to be physically mapped relative to the two other constraints that constitute the framework. This provides an additional dimension with which to provide a complete visualisation and operation of the management of a space, as can be seen with reference to FIG. 3b.

Referring to FIG. 3b, there is shown a diagrammatic representation of a space and volume framework as applied to a restaurant booking system in accordance with the embodiment of the invention. There is shown the three-dimensional framework 302 with dimension x 312, dimension y 314 and dimension z 316, compared to a prior art framework 318 which illustrates a Gantt chart 324 including a first dimension 320 and a second dimension 322.

Referring to FIG. 3c, there is shown a diagrammatic representation of a space and volume framework as applied to a dual diary system in accordance with the embodiment of the invention. In more detail, there is described a practical application of the concept of FIG. 3b where the framework 302 with dimensions x 334, y 336 and z 338 are located within the context of a posting calendar 332, which is arranged to interact with a user-defined reporting calendar 340.

Referring to FIG. 3d, there is shown a diagrammatic representation of a space and volume framework as applied to a restaurant booking system in accordance with the embodiment of the invention. A restaurant floor plan 348 is overlaid on the three-dimensional framework. In more detail, a floor plan creation module 346 is utilised to create a floor plan for a restaurant, including the size and shape of the restaurant space, the creation of sub-areas and sections, the division of the areas and/or sub areas into classes, the addition of tables and chairs (including dimensions), etc. The floor plan is placed in the volumetric framework 358 within the calendar 352, where the x and y axes represent the length and width of the space, and the z axis represents time. As such, each area, sub area, class, table, chair, etc. can be tracked over time. The z axis is controlled by a time constraint module 364 which includes time constraints 366 such as opening hours, seating periods, etc.

In other words, the volumetric framework, in addition to the calendar and the floor creation module and time constraint module create a real time simulation of the restaurant, allowing the operator to track all aspects of the restaurant/space over time. This framework is derived from the realisation that the pivotal structure (both physical and conceptual) in the operation of a space such as a restaurant, is the booking and how the booking is allocated and managed. The placement of tables and chairs, the opening hours, the food served, the staff employed, etc., are ultimately all connected to the booking. As such, the volumetric model is a completely different manner in which to conceptualise the operation of a space (and in particular a restaurant space or any other space where a service is provided and there are multiple constraints).

Referring to FIG. 3e, there is shown a diagrammatic representation of a space and volume framework and the constraints which are applied in the context of a restaurant booking system in accordance with the embodiment of the invention. At 352 there is shown the posting calendar including a volumetric framework 356 and the associated reporting calendar 360. A large number of input values, constraints and rules are provided to the volumetric framework, including a floor plan framework 368, allocation rules 370, menu constraints 372, booking arrival time constraints 374, duration time constraints 376, extend duration constraints 378, promotion constraints 380, distribution channel constraints 382, payment term constraints 384, price constraints 386, terms and conditions constraints 388, booking fee constraints 390, group size constraints 392, occasion constraints 394, customer experience constraints 396, customer ranking and preference constraints 398, personalisation constraints 3100, concierge items 3102 and the time framework 3104.

Referring to FIG. 3f, there is shown a diagrammatic representation of a space and volume framework including processing modules arranged to interact with the volumetric framework as applied to a restaurant booking system in accordance with the embodiment of the invention. As with previous diagrams, the central aspect of the booking and management system is the volumetric framework 356 located within the volumetric calendar 3110 which can then post to a reporting calendar 360. A requestor (i.e. a person making a booking) 3106 interacts with a widget through a widget channel 3108 which in turn is in communication with the volumetric calendar. In allocating a booking, the volumetric calendar selects an algorithm 3114 from a plurality of algorithms 3115 in order to determine whether capacity is available. If capacity is found at 3118, then at 3119 the system proceeds to 3134, where the request is confirmed, and a message is returned to the widget channel 3108. If capacity is not found at 3116, the booking request is sent to the artificial intelligence module 3136, which then at 3138, reviews constraints based on the last booking received, and either amends the constraints and returns the booking request to the calendar 3110, or alternatively, suggests an alternative at 3120 and returns the alternative to the widget channel 3108. The space/volumetric calendar also makes use of a forecasting module 3126, which includes access to a historical database 3124, measurement metrics 3128, weather information 3130 and planned events 3132.

Referring to FIG. 3g, there is shown a diagrammatic representation of a prior art framework as applied to a restaurant booking system in accordance with the embodiment of the invention. There is shown a Gantt chart 399 which is situated within a posting calendar 352. The Gantt chart is capable of being controlled by a table and table combination list module 395, which includes segmenting by areas, such as 391 and 393. There is also provided a promotions module 389 including promotional menus 387 and specific terms and conditions 385. There is also provided a time constraints module 364 including sets of time constraints 366, and a capacity constraints module 383, which includes specific capacity constraints 381, which can be modified to suit the particular circumstances of the restaurant.

Referring to FIG. 3h, there is shown a diagrammatic representation of a framework as applied to a restaurant booking system in accordance with the embodiment of the invention. At 352 there is shown the posting calendar including a conventional Gantt chart 399 and an associated reporting calendar 360. A large number of input values, constraints and rules are provided to the volumetric framework, including a floor plan framework 368, allocation rules 370, menu constraints 372, booking arrival time constraints 374, duration time constraints 376, extend duration constraints 378, promotion constraints 380, distribution channel constraints 382, payment term constraints 384, price constraints 386, terms and conditions constraints 388, booking fee constraints 390, group size constraints 392, occasion constraints 394, customer experience constraints 396, customer ranking and preference constraints 398, personalisation constraints 3100, concierge items 3102 and the time framework 3104.

Referring FIG. 3i, there is shown a diagrammatic representation of a framework as applied to a restaurant booking system in accordance with the embodiment of the invention. As with previous diagrams, the central aspect of the booking and management system is the Gantt chart 399 located within the volumetric calendar 3110 which can then post to a reporting calendar 360. A requestor (i.e. a person making a booking) 3106 interacts with a widget through a widget channel 3108 which in turn is in communication with the volumetric calendar. In allocating a booking, the volumetric calendar selects an algorithm 3114 from a plurality of algorithms 3115 in order to determine whether capacity is available. If capacity is found at 3118, then at 3119 the system proceeds to 3134, where the request is confirmed, and a message is returned to the widget channel 3108. If capacity is not found at 3116, the booking request is sent to the artificial intelligence module 3136, which then at 3138, reviews constraints based on the last booking received, and either amends the constraints and returns the booking request to the calendar 3110, or alternatively, suggests an alternative at 3120 and returns the alternative to the widget channel 3108. The space/volumetric calendar also makes use of a forecasting module 3126, which includes access to a historical database 3124, measurement metrics 3128, weather information 3130 and planned events 3132.

### ADVANTAGES

The embodiment and broader invention described herein provides a number of advantages.

Firstly, the embodiment provides an optimised space allocation instruction set to a user associated with a venue. For example, if the venue is a restaurant, currently the space allocation and arrangement of tables within the space of the venue is currently performed by the restaurant staff, manager or maitre d′. Given the number of possible arrangements and permutations that are possible in a venue with multiple spaces and multiple tables, which can be arranged in multiple ways, any arrangement that is performed “manually” (i.e. a person decides how to arrange the tables) is statistically very likely to be sub-optimal, particularly since the number and size of bookings that will be received (or the time/order/rate at which they will be received) for a service period cannot be known precisely until a short time before the service time. Generally, any arrangement of the venue is based on the experience or preference of the person performing the space allocation and arrangement of tables, and is therefore solely dependent on the experience, knowledge, ingenuity and interest of the person performing the space allocation. Therefore, the computer system of the present invention provides a new, mathematically and logically rigorous means of optimising the use of a venue.

Furthermore, the embodiment also provides additional advantages as the optimisation of the use of the venue can be modified to maximise certain desired outcomes. For example, the rules of the iterative allocation process can be varied to maximise the number of bookings to maximise profits. Alternatively, the iterative allocation process in accordance with the embodiment can be varied to increase customer experience by allocating a specific use of space at a requestor's request or ensuring that the arrangement of space is optimal for user atmosphere and experience. As will be appreciated, the computer system in the present invention provides for a greater level of control over any individual variable or group of variables regarding the operation of the venue and such control is not possible without the ability to allocate bookings in an intelligent manner.

Moreover, as the optimised space allocation instruction sets and user data is retained in the database, the embodiment provides a further means to optimise the operation of the venue by retrospective data analysis. The prediction module disclosed in the present specification is capable of predicting the allocation of space within the venue based on past optimised space allocation instruction sets for the period of time under analysis.

The embodiment also provides an advantage over known online reservation systems, in that the embodiment can engage in a process of negotiation with the booking requestor to generate an allocated booking that balances the constraints of the booking requestor and the venue. In prior art systems, there no opportunity for the reservation system to interact with the booking requestor.

For example, for a venue utilising the invention, the venue has the ability to offer special deals or propose alternate requests in the event that a booking request cannot be accommodated at first instance. Therefore, the embodiment provides a fundamental and crucial advantage over the prior art by enabling a direct two-way connection between the venue and the booking requestor, in a manner that does not require any “manual” intervention by venue staff or management. Furthermore, as disclosed above, the embodiment is capable of determining effective incentives or additional elements that may be added to enhance the use of the space and present the incentives to a booking requestor in an autonomous manner. As a corollary, the incentives are not “pre-programmed”—that is, the embodiment does not merely select from a list of incentives in a sequential manner. Rather, the incentives are generated “on the fly” in response to a number of inputs, including but not limited to the venue constraint information and the requestor constraint information. In a technical sense, the embodiment acts as an intelligent agent, autonomously determining incentives that operate to balance and maximise both the utility of the booking requestor and the yield of the venue.

From another perspective, the embodiment described herein provides a user interface that permits a sophisticated and directed interaction between the embodiment, acting as an intelligent agent for the venue, and the booking requestor, to accommodate a booking request in a manner that maximises the interests of the venue and the booking requestor. This advantage is achieved, in part, through the use of an interface that is dynamically adaptive by, in response to venue constraint information and requestor constraint information, with the ability to generate multiple potential solutions utilising different menus, time durations, seats, tables, pricing levels based on different times and durations using dynamic pricing models, different rooms, and packages.

Embodiments of the present invention make allowance for different products or a suite of products that a venue is capable of offering at different booking intervals during a service period. For example, to optimise revenue, a venue such as a restaurant must have information regarding the products and services the restaurant is capable of providing and make allowance for other constraints that may be affected as a result of a booking requestor requesting specific products and services. As a simple example, a restaurant can offer an a la carte menu from which diners can select one, two or three courses for their meal. Further, from historical knowledge of the restaurant's design, service standards, cooking techniques, the average time required to consume the food etc., determine that an appropriate duration for a one course meal is 1 hour, a two-course meal 1½ hours and a 3 course meal 2 hours. This knowledge allows the allocation module and the requestor user interface to allocate appropriate resources, but more importantly, allows the allocation module to determine whether a booking can be allocated and subsequently adequately serviced. The prior art is fundamentally incapable of performing such a sophisticated determination. In the known art, most restaurants choose an arbitrary “safe” meal duration time, the duration time being selected such that it encompasses the longest reasonable duration (e.g. two hours) so that the probability of conflicting bookings is minimised. However, this limitation incorporates an inefficiency into the booking process which disadvantages both the restaurant (as the restaurant is inherently limited in the number of allocations that can be offered) and the booking requestor, who is only able to make a booking within the limited constraints provided by the restaurant. The embodiment described herein ameliorates this problem by providing a system which is capable of “negotiating” an outcome that maximises the utility of the booking requestor while simultaneously maximising the yield of the restaurant.

Embodiments of the invention include the ability to offer alternatives to a booking requestor. For example, the embodiment is able to advise a booking requestor that a two hour period is not available for their booking preferred booking time a 1½ hour booking is available should they be satisfied with a two course meal. In other words, the system is capable of attempting to negotiate a suitable compromise position with the booking requestor, thereby increasing the likelihood of securing the booking, while also maximising the utility to the booking requestor, within the constraints of the venue and the requestor.

Embodiments of the invention are capable of differentiating between the times that are required or should be offered for different menus, different courses or different offerings so that the amount of time required by a booking can be optimised thereby optimising the use of the space.

Embodiments of the invention include a multi-venue capability whereby each venue within a group of venues can be included in the same group. Where venues are located in different time zones, the venues correctly display the correct time to avoid confusion and errors in booking times when bookings are made for different venues in the same group.

Embodiments of the invention include all information and data utilised by multi-venue groups to be available to all venues within the group such that where a booking cannot be allocated to one venue in the group, the booking requestor can be offered a different nearby venue in the group. Similarly, booking constraint information utilised in booking one venue can be utilised in booking another venue.

Embodiments of the invention include the ability to change the diary page format to accommodate different activities that a restaurant may wish to undertake. For example the prior art cannot confirm a booking for a private room within a restaurant as; firstly the booking widget cannot cater for the booking request; secondly, the booking widget does not have the ability to request the right information; and third, the diary setup cannot cater for a function booking.

Embodiments of the invention review the actual revenue received against a calculated “maximum potential revenue” to determine the level of discounting (explicit or implicit) that was applied to achieve the actual revenue gained. This metric, termed the “revenue yield” is a measure of the revenue achieved versus the total possible revenue where all sales and complementary items are calculated at full price.

Embodiments of the invention calculate and monitor actual booking duration times (rather than utilising hypothetical or fixed booking during times) and the duration times can be analysed by menu, by courses selected, by occasion, by group size, wherein the resultant analysis can be used as an input to determine appropriate allocations for booking times and benchmarks for forecasting rather than a simplistic generalisation provided by the prior art.

Embodiments of the system advantageously allow for the forecasting of potential revenue, profit, etc., utilising algorithms that optimise for the best use of available resources, given a specific pool of booking requests (both historical and projected).

Moreover, embodiments of the invention are intuitive in that the algorithms encoded in the system assist in the forecasting of future events, demand and provide feedback which enables the further development of capacity and revenue generation.

Embodiments of the invention advantageously interrogate any unused or unallocated spaces or tables and automatically notify potential booking requestors of the availability, potentially applying a dynamic price to such promotions and thereby increasing yield and optimising use of available resources.

Embodiments advantageously allow a booking requestor to make one booking request to book two allocation portions within the same venue. For example, where the venue is a restaurant, the requestor may book a seat at the bar for 7 pm and a table in the main dining room for 7:30 pm.

The embodiment, from a technical perspective, is able to utilise the size and floor space of the restaurant and its spatial characteristics to determine which tables or areas have a higher utility than others or where to place tables. Furthermore, the embodiment is capable of segmenting the restaurant into multiple areas (where an area can also comprise a separate room, a separate level and any venue can be split into multiple areas irrespective of physical barriers such as walls within the venue) which can then be further divided into subspaces, sections and or classes for the allocation of bookings. Specifically, the prior art is unable to recognise different areas beyond simple numbering or table referencing.

The embodiment is capable of utilising information provided by a customer when making a booking request to provide recommendations to the person making the booking request. For example, if a customer were to advise the occasion for their booking was their anniversary and the booking was for two people, menu recommendations and table selections offered could be completely different to the menu and the table selection offered to a table for two having a business meeting on a time limit. The prior art cannot compare recommendations and autonomous settings by the system compared to manual settings and manual over-rides and evaluate which solution and outcome was better and make recommendations and further adjustments.

The embodiment is capable of determining the optimum ratio of fixed versus flexible seating and updates the ratio based on historical information of unfulfilled booking requests in order to minimise future bookings that cannot be accepted.

The embodiment advantageously provides a dashboard, designed as a “cockpit” such that all relevant information is visible on the screen at all points in time including a communications panel including a dynamic floor plan and Gantt chart.

The embodiment is advantageously capable of delaying the first allocation of booking requests to the tables and table combinations as each individual booking request is allocated on receipt of that booking request. Specifically, the embodiment delays the first allocation process until a certain “threshold” target is reached. The process of allocating each booking as soon as it is received does not offer any benefits and creates “barriers” to the acceptance of subsequent bookings.

The embodiment advantageously capable of classifying tables and table combinations into different categories such that individual booking requests can be applied to different categories and a different priority and allocation process which may include the process of a guaranteed allocation to a specific table not permitted by the prior art.

The system advantageously provides a table configurator and simulator to determine the optimal size table, quantity of tables, orientation of seating, size and quantity of fixed versus flexible seating, to thereby be used in the planning of a restaurant or in the revision of a restaurant arrangement.

The embodiment advantageously allows for dynamic variations in capacity, thereby maximising efficient use of resources.

Dynamic variation may be coupled with yield management, as the system is capable of utilising yield management techniques to optimise bookings, and also to provide a better, more customised service to the booking requestor. Yield management is performed, in part, by an understanding of the products and services available to the requestor, wherein the system uses constraint information to optimise for various constraints while maximising yield.

The use of the computer-enabled method, system and computer program disclosed herein has provided examples within the restaurant industry, however, they are equally applicable within other industries and businesses such as airlines, accommodation, hotels, travel, cruise ships, car rentals, clubs, pubs, gyms, hairdressers, workspaces, and the provision of advice and consulting services.

### DISCLAIMERS

Throughout this specification, unless the context requires otherwise, the word “comprise” or variations such as “comprises” or “comprising”, will be understood to imply the inclusion of a stated feature or group of features but not the explicit exclusion of any other feature or group of features.

Those skilled in the art will appreciate that the embodiments described herein are susceptible to obvious variations and modifications other than those specifically described and it is intended that the broadest claims cover all such variations and modifications. Those skilled in the art will also understand that the inventive concept that underpins the broadest claims may include any number of the steps, features, and concepts referred to or indicated in the specification, either individually or collectively, and any and all combinations of any two or more of the steps or features may constitute an invention.

Where definitions for selected terms used herein are found within the detailed description of the invention, it is intended that such definitions apply to the claimed invention. However, if not explicitly defined, all scientific and technical terms used herein have the same meaning as commonly understood to one of ordinary skill in the art to which the invention belongs.

Although not required, the embodiments described with reference to the method, computer program, computer interface and aspects of the system can be implemented via an Application Programming Interface (API), an Application Development Kit (ADK) or as a series of program libraries, for use by a developer, for the creation of software applications which are to be used on any one or more computing platforms or devices, such as a terminal or personal computer operating system or a portable computing device, a smartphone or a tablet computing system operating system, or within a larger server structure, such as a ‘data farm’ or within a larger computing transaction processing system.

Generally, as program modules include routines, programs, objects, components and data files that perform or assist in the performance of particular functions, it will be understood that the functionality of the method, computer program and computer interface defined herein may be distributed across a number of routines, programs, objects or components to achieve the same functionality as the embodiment and the broader invention claimed herein. Such variations and modifications are contemplated by the inventor and are within the purview of those skilled in the art.

It will also be appreciated that where methods and systems of the present invention and/or embodiments are implemented by computing systems or implemented across multiple computing systems then any appropriate computing system architecture may be utilised without departing from the inventive concept. This includes standalone computers, networked computers and dedicated computing devices that do not utilise software as it is colloquially understood (such as field-programmable gate arrays).

Where the terms “computer”, “computing system”, “computing device” and “mobile device” are used in the specification, these terms are intended to cover any appropriate arrangement of computer hardware for implementing the inventive concept and/or embodiments described herein.

Where the terms “software application”, “application”, “app”, “computer program”, “program” and “widget” are used in the specification when referring to an embodiment of the invention, these terms are intended to cover any appropriate software which is capable of performing the functions and/or achieving the outcomes as broadly described herein.

Where reference is made to communication standards, methods and/or systems, it will be understood that the devices, computing systems, servers, etc., that constitute the embodiments and/or invention or interact with the embodiments and/or invention may transmit and receive data via any suitable hardware mechanism and software protocol, including wired and wireless communications protocols, such as but not limited to second, third, fourth and fifth generation (2G, 3G, 4G and 5G) telecommunications protocols (in accordance with the International Mobile Telecommunications-2000 (IMT-2000) specification), Wi-Fi (in accordance with the IEEE 802.11 standards), Bluetooth (in accordance with the IEEE 802.15.1 standard and/or standards set by the Bluetooth Special Interest Group), or any other radio frequency, optical, acoustic, magnetic, or any other form or method of communication that may become available from time to time.

1. A computer-enabled method for optimising and allocating bookings to one or more spaces, the method optimising bookings to increase the probability of achieving a selected outcome, comprising the steps of, receiving, at a pre-allocation module in communication with a processor, a booking request from a remote user interface via a communications network, the booking request including initial booking request information including at least a date and a time of the booking and a number of diners and a booking identifier,
the pre-allocation module utilising the initial booking request information to determine whether the initial booking request information satisfies a plurality of booking constraints,
whereby, if the request information does not satisfy one or more of the plurality of booking constraints, the pre allocation module invokes an artificial intelligence module arranged to receive the request information and review one or more of the plurality of constraints including forecasted bookings and already accepted bookings to determine whether variation of the one or more constraints to allow acceptance of the booking request result in a greater maximisation in the probability of achieving the selected outcome, whereby if variation of the one or more constraints to allow acceptance of the booking request results in an increase in the probability of achieving the selected outcome, the one of more of the plurality of constraints are varied, and the initial booking request information is passed to an allocation module arranged to accept the booking request and allocate the booking request together with all previously received requests to one or more spaces in the venue, whereby if all booking requests can be allocated the received booking request is accepted,
whereby the booking information is utilised to produce an optimised allocation instruction set saved on a database which is utilisable by one or more users associated with the venue.

2-65. (canceled)
